(19) United States
(12) Patent Application Publication
(10) Pub. No.: US 2025/0046773 A1
(43) Pub. Date: Feb. 6, 2025

(54) INSULATION CHIP AND SEMICONDUCTOR DEVICE

(71) Applicant: ROHM CO., LTD., Kyoto-shi (JP)

(72) Inventors: Masanobu TSUJI, Kyoto-shi (JP); Bungo TANAKA, Kyoto-shi, (JP)

(21) Appl. No.: 18/790,396

(22) Filed: Jul. 31, 2024

(30) Foreign Application Priority Data
Aug. 2, 2023 (JP) 2023-126076

(51) Int. Cl. H01L 25/16; H01F 27/28; H01L 23/00; H01L 23/31; H01L 23/495; H01L 23/544

(52) U.S. Cl. CPC H01L 25/162; H01F 27/2804; H01L 23/3135; H01L 23/49575; H01L 28/10; H01L 23/544; H01L 24/16; H01L 24/32; H01L 24/48; H01L 24/73; H01L 2223/54426; H01L 2224/16237; H01L 2224/32245; H01L 2224/48245; H01L 2224/73207; H01L 2224/73253; H01L 2224/73265

(57) ABSTRACT

A semiconductor device includes a first unit, a second unit, and a third unit placed on the first unit and on the second unit. The first unit includes a first semiconductor substrate, a first element insulating layer, and a first insulation element. The second unit includes a second semiconductor substrate, a second element insulating layer, and a second insulation element. The third unit includes a third semiconductor substrate, a third element insulating layer, a third insulation element, and a fourth insulation element. In a unit arrangement state, the first insulation element and the third insulation element are placed to face each other in the Z-direction, and the second insulation element and the fourth insulation element are placed to face each other in the Z-direction.

### CROSS-REFERENCE TO RELATED APPLICATIONS

This application is based upon and claims the benefit of priority from prior Japanese Patent Application No. 2023-126076, filed on Aug. 2, 2023, the entire contents of which are incorporated herein by reference.

### BACKGROUND

### 1. Field

The present disclosure relates to an insulation chip and a semiconductor device.

### 2. Description of Related Art

Japanese Laid-Open Patent Publication No. 2018-78169 discloses a transformer chip including a semiconductor substrate, an insulating layer laminate structure formed on the substrate, and an upper coil and a lower coil formed in the insulating layer laminate structure.

### BRIEF DESCRIPTION OF THE DRAWINGS

FIG. 1 is a schematic circuit diagram of a semiconductor device according to a first embodiment.

FIG. 2 is a schematic plan view of the semiconductor device of FIG. 1.

FIG. 3 is a schematic cross-sectional view of the semiconductor device taken along line F3-F3 in FIG. 2.

FIG. 4 is a schematic plan view of a first unit of the semiconductor device of FIG. 2.

FIG. 5 is a schematic cross-sectional view of the first unit taken along line F5-F5 in FIG. 4.

FIG. 6 is a schematic plan view of a second unit of the semiconductor device of FIG. 2.

FIG. 7 is a schematic cross-sectional view of the second unit taken along line F7-F7 in FIG. 6.

FIG. 8 is a schematic plan view of a third unit of the semiconductor device of FIG. 2.

FIG. 9 is a schematic cross-sectional view of the third unit taken along line F9-F9 in FIG. 8.

FIG. 10 is an enlarged schematic cross-sectional view of the first unit, the second unit, the third unit, and their surrounding area in FIG. 3.

FIG. 11 is a schematic plan view of a third unit of a semiconductor device of a second embodiment.

FIG. 12 is a schematic cross-sectional view of the semiconductor device taken along line F12-F12 in FIG. 11.

FIG. 13 is a schematic plan view of a second coil, a third coil, and a connection wiring line of a modification of the semiconductor device of the second embodiment.

FIG. 14 is a schematic plan view of a second coil, a third coil, and a connection wiring line of a modification of the semiconductor device of the second embodiment.

FIG. 15 is a schematic plan view of a semiconductor device according to a third embodiment.

FIG. 16 is a schematic cross-sectional view of the semiconductor device taken along line F16-F16 in FIG. 15.

FIG. 17 is a schematic cross-sectional view of the semiconductor device in which the third unit is separated from the first unit.

FIG. 18 is a schematic plan view of a semiconductor device of a modification of the semiconductor device of the third embodiment.

FIG. 19 is a schematic cross-sectional view of the semiconductor device taken along line F19-F19 in FIG. 18.

FIG. 20 is a schematic plan view of a semiconductor device of a modification of the semiconductor device of the third embodiment, in which the third unit is omitted.

FIG. 21 is a schematic cross-sectional view of the semiconductor device taken along line F21-F21 in FIG. 20, in which the third unit is separated from the first and second units.

FIG. 22 is a schematic cross-sectional view of a semiconductor device according to a modification.

FIG. 23 is a schematic cross-sectional view of a semiconductor device according to a modification.

FIG. 24 is a schematic plan view of a semiconductor device according to a modification.

FIG. 25 is a schematic cross-sectional view of a semiconductor device according to a modification.

FIG. 26 is a schematic cross-sectional view of a semiconductor device according to a modification.

FIG. 27 is a schematic cross-sectional view of a semiconductor device according to a modification.

Throughout the drawings and the detailed description, the same reference characters refer to the same elements. The drawings may not be to scale, and the relative size, proportions, and depiction of elements in the drawings may be exaggerated for clarity, illustration, and convenience.

### DETAILED DESCRIPTION

This description provides a comprehensive understanding of the methods, apparatuses, and/or systems described. Modifications and equivalents of the methods, apparatuses, and/or systems described are apparent to one of ordinary skill in the art. Sequences of operations are exemplary, and may be changed as apparent to one of ordinary skill in the art, with the exception of operations necessarily occurring in a certain order. Descriptions of functions and constructions that are well known to one of ordinary skill in the art may be omitted.

Exemplary embodiments may have different forms, and are not limited to the examples described. However, the examples described are thorough and complete, and convey the full scope of the disclosure to one of ordinary skill in the art.

Embodiments of an insulation chip and a semiconductor device in accordance with the present disclosure will now be described with reference to the accompanying drawings. In the drawings, components may not be drawn to scale for simplicity and clarity of illustration. In a cross-sectional view, hatching may be omitted to facilitate understanding. The accompanying drawings are merely illustrative of embodiments of the disclosure and should not be considered as limiting the disclosure. Terms such as “first”, “second”, and “third” in this disclosure are used to distinguish subjects and not used for ordinal purposes.

This detailed description provides a comprehensive understanding of the methods, apparatuses, and/or systems described. This detailed description is merely intended for explanatory purposes, and does not intend to limit the embodiments of the present disclosure, nor the application or usage of such embodiments.

The expression “at least one” as used herein means “one or more” of desired options. As an example, the expression “at least one” as used herein means “only one option” or “both of two options” if the number of options is two. As another example, the expression “at least one” used herein means “only one option” or “a combination of any two or more options” if the number of options is three or more.

As used herein, “the length (dimension) of A is equal to the length (dimension) of B” or “the length (dimension) of A and the length (dimension) of B are equal to each other” includes a relationship in which the difference between the length (dimension) of A and the length (dimension) of B is, for example, within 10% of the length (dimension) of A.

### First Embodiment

### Schematic Configuration of Semiconductor Device

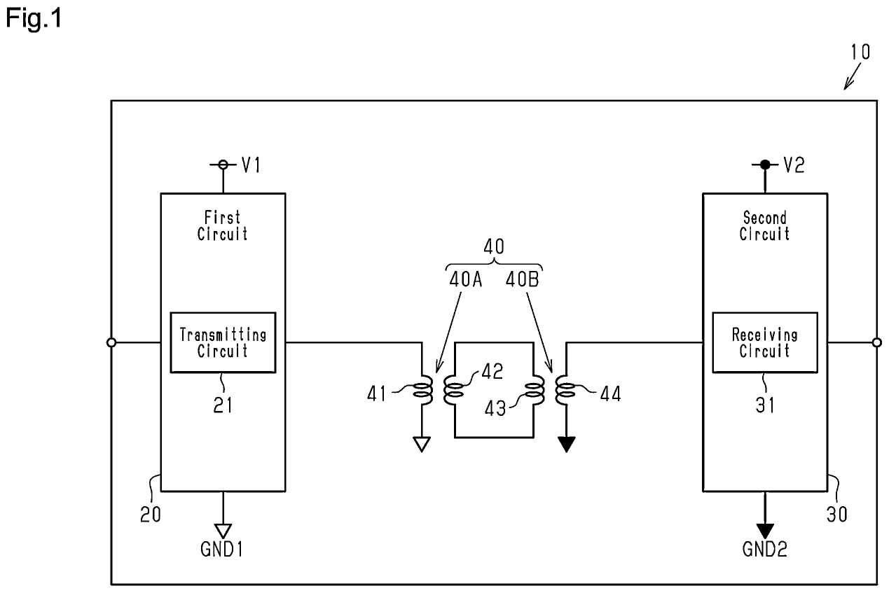

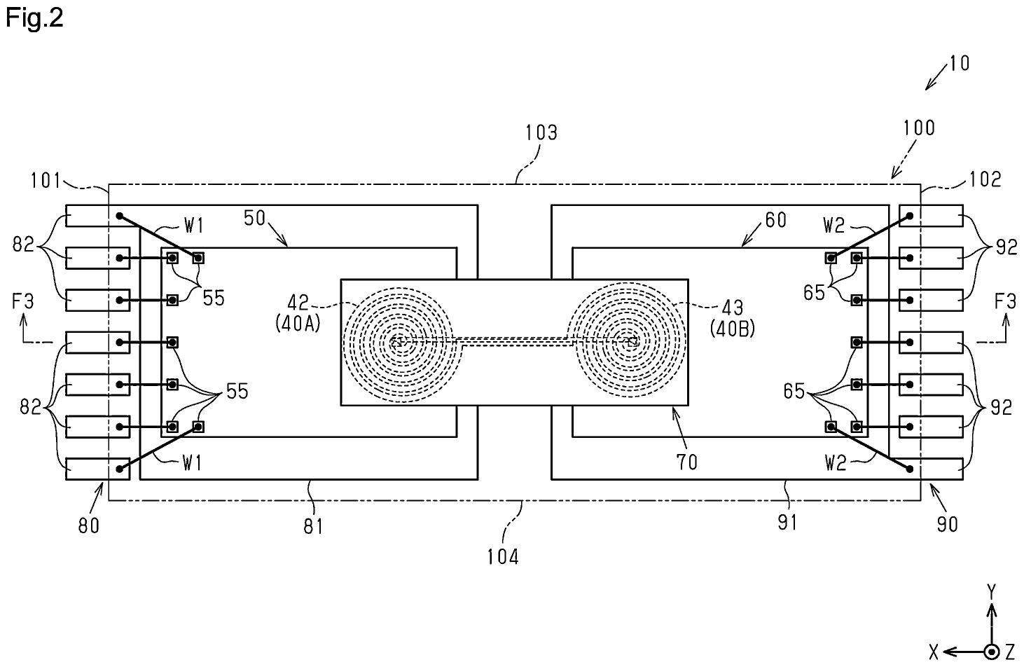

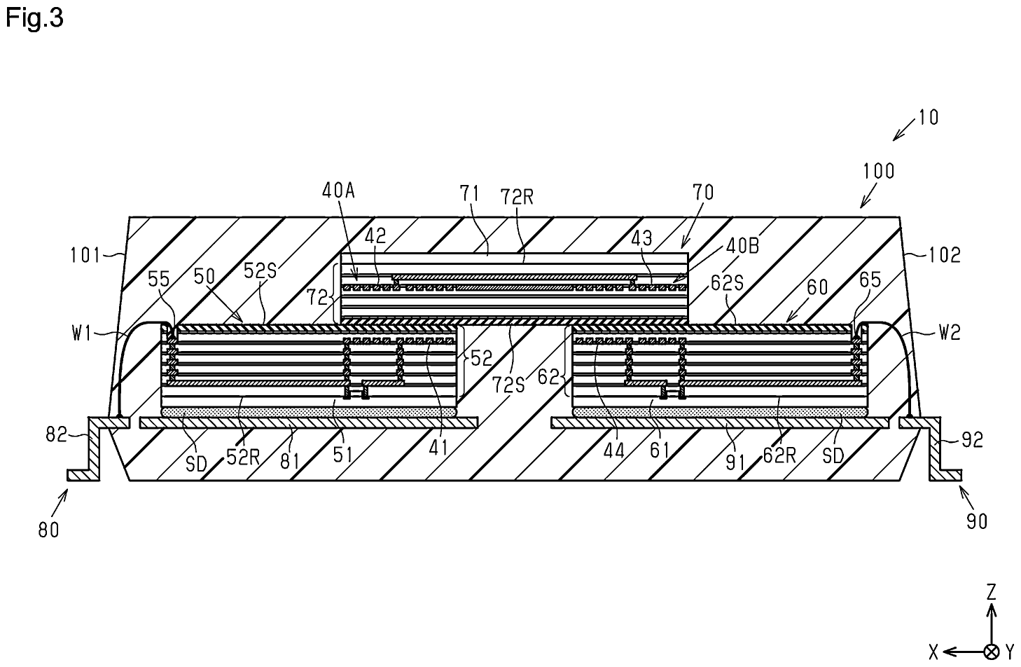

Referring to FIGS. 1 to 3, the schematic configuration of a semiconductor device 10 of a first embodiment is now described. FIG. 1 schematically illustrates the circuit configuration of the semiconductor device 10 according to the first embodiment. FIG. 2 schematically shows an example of the internal configuration (planar structure) of the semiconductor device 10. To show the internal configuration of the semiconductor device 10, FIG. 2 indicates sealing plastic 100, which will be described below, with the long dash double-short-dash line. FIG. 3 schematically shows a cross-sectional structure of the semiconductor device 10 shown in FIG. 2 taken along line F3-F3.

FIG. 1 illustrates the circuit configuration of the semiconductor device 10 in a simplified manner, so that the number of external terminals of the semiconductor device 10 in FIG. 2 is greater than the number of external terminals of the semiconductor device 10 in FIG. 1. The number of external terminals of the semiconductor device 10 refers to the number of external electrodes capable of connecting the semiconductor device 10 to electronic components external to the semiconductor device 10.

As shown in FIG. 1, the semiconductor device 10 includes a first circuit 20, a second circuit 30, and a transformer 40. The transformer 40 provides electrical insulation between the first circuit 20 and the second circuit 30.

The first circuit 20 is configured to operate with a first voltage V1. In one example, the first circuit 20 includes a transmitting circuit or a receiving circuit. In the first embodiment, the first circuit 20 includes a transmitting circuit 21. The transmitting circuit 21 includes at least one transistor. The second circuit 30 is configured to operate with a second voltage V2. In one example, the second circuit 30 includes a transmitting circuit or a receiving circuit. In the first embodiment, the second circuit 30 includes a receiving circuit 31. The receiving circuit 31 includes at least one transistor. The first voltage V1 and the second voltage V2 may be the same or different from each other. In one example, the second voltage V2 is equal to the first voltage V1. The semiconductor device 10 may be referred to as a digital isolator. Thus, the semiconductor device 10 may be considered as a signal transmission device that transmits a signal from the first circuit 20 to the second circuit 30.

The transformer 40 includes a first transformer 40A connected to the transmitting circuit 21 of the first circuit 20 and a second transformer 40B connected to the receiving circuit 31 of the second circuit 30. The first and second transformers 40A and 40B are connected in series. In this manner, the transformer 40 has a structure that provides double insulation between the first and second circuits 20 and 30.

The first transformer 40A includes a first coil 41 and a second coil 42. The second transformer 40B includes a third coil 43 and a fourth coil 44. The first coil 41 is electrically connected to the transmitting circuit 21 of the first circuit 20. The fourth coil 44 is electrically connected to the receiving circuit 31 of the second circuit 30. The second coil 42 and the third coil 43 are electrically connected to each other.

The transmitting circuit 21 of the first circuit 20 receives an input signal and pulses the first transformer 40A. The pulse signal excited in the first coil 41 of the first transformer 40A is transmitted through the second coil 42 of the first transformer 40A and the third and fourth coils 43 and 44 of the second transformer 40B, and is input to the receiving circuit 31 of the second circuit 30. The receiving circuit 31 outputs an output signal based on the input pulse signal.

### Internal Configuration of Semiconductor Device

As shown in FIG. 2, in the semiconductor device 10, a first unit 50, a second unit 60, and a third unit 70 of semiconductor chips are packaged into a single package. In this specification, the semiconductor chip formed by the first unit 50, the second unit 60, and the third unit 70 is referred to as an “insulation chip 40P”. In the first embodiment, the insulation chip 40P is a transformer chip.

The package format of the semiconductor device 10 is a small outline (SO) type, and is a small outline package (SOP) in the first embodiment. The package format of the semiconductor device 10 may be freely modified. The package format is not limited to SOP, but may be quad for non-lead package (QFN), dual flat package (DFP), dual inline package (DIP), quad flat package (QFP), single inline package (SIP), or small outline J-leaded package (SOJ), or various similar package structures.

The semiconductor device 10 includes the first unit 50, the second unit 60, the third unit 70, a first lead frame 80, a second lead frame 90, and the sealing plastic 100. The sealing plastic 100 is configured to seal the first unit 50, the second unit 60, and the third unit 70, and also to partially seal the first lead frame 80 and the second lead frame 90. In FIG. 2, for the convenience of illustrating the internal configuration of the semiconductor device 10, the sealing plastic 100 is indicated by the long-dash double-short-dash line.

The sealing plastic 100 is made of an electrically insulating resin material. The resin material may include a black epoxy resin, for example. The sealing plastic 100 has a rectangular plate shape having a thickness direction in the Z-direction. The sealing plastic 100 includes four sealing side surfaces 101 to 104. More specifically, the sealing plastic 100 includes sealing side surfaces 101 and 102 as opposite end surfaces in the X-direction, and sealing side surfaces 103 and 104 as opposite end surfaces in the Y-direction. The X and Y-directions are perpendicular to the Z-direction. The X-direction and the Y-direction are perpendicular to each other as viewed from the Z-direction. As viewed from the Z-direction, the sealing plastic 100 has a rectangular shape having a longitudinal direction in the X-direction and a transverse direction in the Y-direction. The X-direction corresponds to the “first direction”. In the following description, “in plan view” refers to viewing from the Z-direction.

Each of the first lead frame 80 and the second lead frame 90 is a conductor, and is made of a material including copper (Cu), iron (Fe), aluminum (Al), or the like. Each of the lead frames 80 and 90 is provided to extend across both the interior and exterior of the sealing plastic 100.

The first lead frame 80 has a first die pad 81, which is within the sealing plastic 100, and multiple first leads 82, which are provided to extend across both the interior and exterior of the sealing plastic 100. Each first lead 82 forms an external terminal electrically connecting the semiconductor device 10 to an external electronic device.

The first unit 50 is mounted on the first die pad 81. In plan view, the first die pad 81 is placed such that its center in the X-direction is closer to the sealing side surface 101 than the center of the sealing plastic 100 in the X-direction is. In the first embodiment, the first die pad 81 is not exposed from the sealing plastic 100. In one example, the first die pad 81 is rectangular and has a longitudinal direction in the X-direction and a transverse direction in the Y-direction.

The first leads 82 are arranged to be spaced apart from one another in the Y-direction. Of the multiple first leads 82, the first lead 82 placed at the end portion near the sealing side surface 103 in the Y-direction is integral with the first die pad 81. The other first leads 82 are arranged to be spaced apart from the first die pad 81 in the X-direction. A portion of each first lead 82 protrudes outward from the sealing side surface 101 of the sealing plastic 100.

The second lead frame 90 includes a second die pad 91, which is within the sealing plastic 100, and multiple second leads 92, which are provided to extend across both the interior and exterior of the sealing plastic 100. Each second lead 92 forms an external terminal electrically connecting the semiconductor device 10 to an external electronic device.

The second unit 60 is mounted on the second die pad 91. In plan view, the second die pad 91 is placed closer to the sealing side surface 102 than the first die pad 81 is in the X-direction. In other words, the first die pad 81 and the second die pad 91 are arranged to be spaced apart from each other in the X-direction. As such, the X-direction may be considered as the arrangement direction of the two die pads 81 and 91. The first and second units 50 and 60 may be considered as being arranged to be spaced apart from each other in the X-direction. In the first embodiment, the second die pad 91 is not exposed from the sealing plastic 100. In one example, the second die pad 91 is rectangular and has a longitudinal direction in the X-direction and a transverse direction in the Y-direction in plan view.

The second leads 92 are arranged to be spaced apart from one another in the Y-direction. Of the multiple second leads 92, the second lead 92 placed at the end portion near the sealing side surface 104 in the Y-direction is integral with the second die pad 91. The other second leads 92 are arranged to be spaced apart from the second die pad 91 in the X-direction. A portion of each second lead 92 protrudes outward from the sealing side surface 102 of the sealing plastic 100.

In the first embodiment, the number of the second leads 92 is the same as the number of the first leads 82. As can be seen from FIG. 2, the first leads 82 and the second leads 92 are arranged in a direction (Y-direction) perpendicular to the arrangement direction (X-direction) of the first and second die pads 81 and 91 in plan view. The number of second leads 92 and the number of first leads 82 may be freely modified. In one example, the number of first leads 82 may differ from the number of second leads 92.

In the first embodiment, the first die pad 81 is supported by the first lead 82 that is integral with the first die pad 81. The second die pad 91 is supported by the second lead 92 that is integral with the second die pad 91. Thus, the die pads 81 and 91 do not have a suspension lead exposed from the sealing side surface 103, 104. This allows for a large insulation distance (creepage distance) between the first and second lead frames 80 and 90.

The first unit 50 mounted on the first die pad 81 is a semiconductor chip including the first circuit 20 and the first coil 41 of the first transformer 40A in FIG. 1. The first unit 50 has the shape of a rectangle having short sides and long sides in plan view. In plan view, the first unit 50 is mounted on the first die pad 81 such that its long sides extend in the X-direction and its short sides extend in the Y-direction. As shown in FIG. 3, the first unit 50 is bonded to the first die pad 81 by a conductive bonding material SD. The conductive bonding material SD may be solder paste, silver (Ag) paste, or the like. The first coil 41 in the first unit 50 is an example of a “first insulation element”.

As shown in FIG. 2, the second unit 60 mounted on the second die pad 91 is a semiconductor chip including the second circuit 30 and the fourth coil 44 of the second transformer 40B in FIG. 1. The second unit 60 has the shape of a rectangle having short sides and long sides in plan view. In plan view, the second unit 60 is mounted on the second die pad 91 such that its long sides extend in the X-direction and its short sides extend in the Y-direction. As shown in FIG. 3, the second unit 60 is bonded to the second die pad 91 by a conductive bonding material SD. The fourth coil 44 in the second unit 60 is an example of a “second insulation element”.

In order for the semiconductor device 10 to have a preset dielectric strength, the first die pad 81 and the second die pad 91, at which the two lead frames 80 and 90 are closest to each other, need to be spaced apart from each other. In one example, the distance between the first and second units 50 and 60 in the X-direction may be greater than or equal to the dimension of the first unit 50 in the Z-direction, for example. Also, this distance may be greater than or equal to the dimension of the second unit 60 in the Z-direction, for example.

As shown in FIGS. 2 and 3, the third unit 70 is placed on the first unit 50 and on the second unit 60 so as to extend over the space between the first and second units 50 and 60 in the X-direction in plan view. The third unit 70 is a semiconductor chip including the second coil 42 of the first transformer 40A and the third coil 43 of the second transformer 40B. The third unit 70 has the shape of a rectangle having short sides and long sides in plan view. In plan view, the third unit 70 is mounted on the first unit 50 and on the second unit 60 such that its long sides extend in the X-direction and its short sides extend in the Y-direction. As shown in FIG. 2, in the first embodiment, the dimension of the third unit 70 in the Y-direction is less than the dimension of the first unit 50 in the Y-direction and the dimension of the second unit 60 in the Y-direction. The second coil 42 included in the third unit 70 is an example of a “third insulation element”, and the third coil 43 included in the third unit 70 is an example of a “fourth insulation element”.

The configuration of the semiconductor device 10 shown in FIGS. 1 to 3 is merely an example, and the circuit configurations included in the first unit 50 and the second unit 60 may be modified as appropriate. The first circuit 20 may include circuits other than the transmitting circuit 21. The second circuit 30 may include circuits other than the receiving circuit 31. For example, the first circuit 20 may include an analog-to-digital conversion circuit. In this case, the semiconductor device 10 is configured as an isolated A/D conversion device.

Furthermore, the second circuit 30 may include a driver circuit that drives the gate of a switching element, for example. The driver circuit may be connected to an external terminal of the semiconductor device 10 (in one example, the second lead 92 shown in FIG. 2). In this case, the semiconductor device 10 is configured as an insulated gate driver that drives a switching element. The switching element may be a power semiconductor element, such as Si metal oxide semiconductor field-effect transistor (SiMOSFET), SiCMOSFET, and insulated-gate bipolar transistor (IGBT). The driver circuit is typically a half-bridge circuit in which a low-side switching element and a high-side switching element are connected in a totem-pole configuration.

The semiconductor device 10 used as an insulated gate driver applies a drive voltage signal to the control terminal of the switching element. In this case, the transmitting circuit 21 of the first circuit 20 converts a control signal input from a controller into a pulse signal, for example. The driver circuit of the second circuit 30 outputs a drive voltage signal to the control terminal of the switching element in response to a signal received by the receiving circuit 31 through the first and second transformers 40A and 40B.

Thus, in the semiconductor device 10 used as an insulated gate driver, the power supply voltage of the first circuit 20, which receives a signal from the controller, is 5 V, 3.3 V, or the like with respect to the ground potential. As for the second circuit 30 connected to the high-side switching element, a voltage equivalent to the voltage applied to the drain of the high-side switching element (for example, 600 V or more) is transiently applied. For this reason, the semiconductor device 10 needs to have a certain dielectric strength between the first circuit 20 and the second circuit 30, more specifically, between the first coil 41 and the second coil 42 of the first transformer 40A and between the third coil 43 and the fourth coil 44 of the second transformer 40B. This dielectric strength is in the range of 2500 Vrms and 7500 Vrms. In one example, the dielectric strength of the semiconductor device 10 is about 5000 Vrms. However, the specific value of the dielectric strength of the semiconductor device 10 is not limited to this and may be any value.

### Detailed Configuration of Insulation Chip

Referring to FIGS. 2 to 10, an example of the configuration of the insulation chip 40P is described. In the following description, of the Z-directions, the direction from the first die pad 81 (second die pad 91) shown in FIG. 3 toward the third unit 70 is defined as the upward direction, and the direction from the third unit 70 toward the first die pad 81 (second die pad 91) is defined as the downward direction.

### First Unit

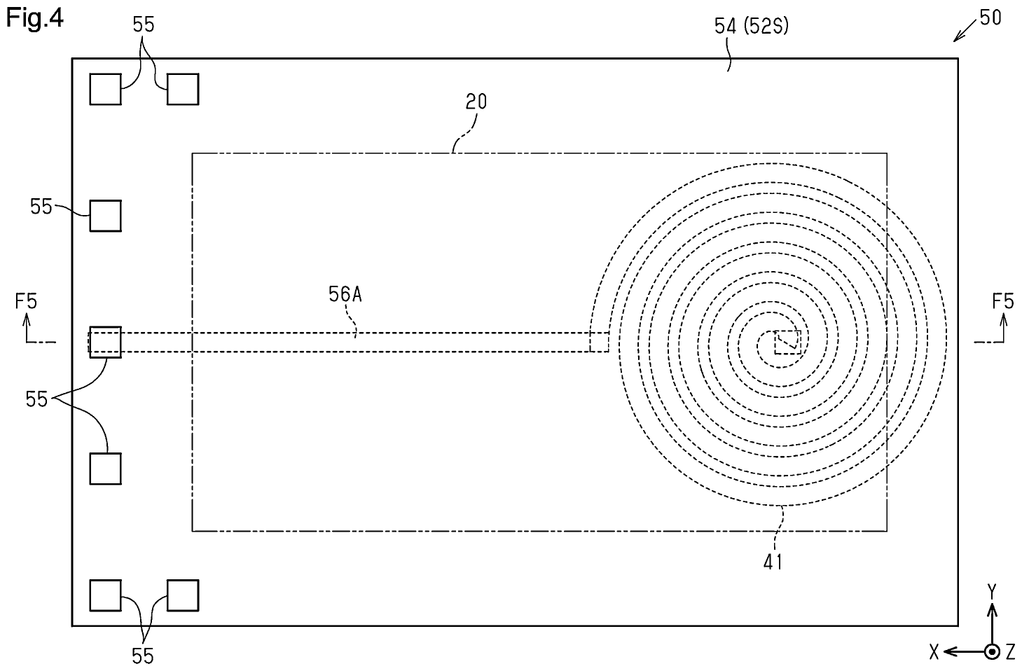

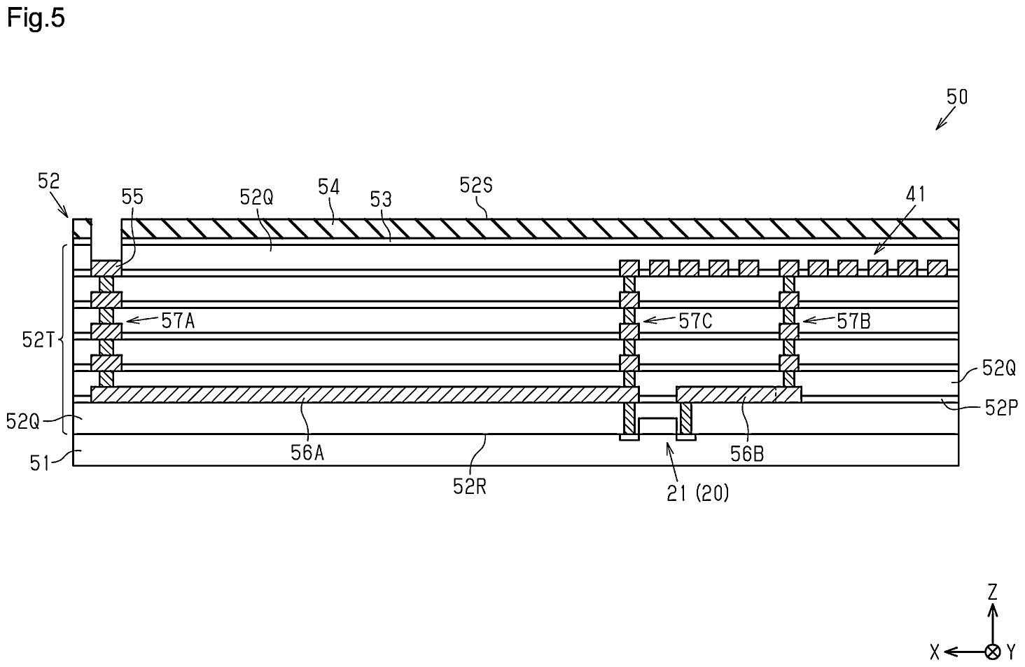

Referring to FIGS. 2 to 5, the configuration of the first unit 50 of the insulation chip 40P is now described. FIG. 4 schematically shows a planar structure of the first unit 50. FIG. 5 shows a schematic cross-sectional structure of the first unit 50 taken along line F5-F5 in FIG. 4. In FIG. 5, one transistor of the transmitting circuit 21 is shown as the transmitting circuit 21.

As shown in FIGS. 2 and 4, the first unit 50 includes multiple first pads 55. The first pads 55 are electrically connected to the first circuit 20. The first pads 55 are individually connected to the first leads 82 by wires W1. The first pads 55 are made of a material including one or more of titanium (Ti), titanium nitride (TiN), gold (Au), Ag, Cu, aluminum (Al), and tungsten (W) appropriately selected. Each wire W1 is a bonding wire formed by a wire bonding device, and is made of a conductor including Au, Al, Cu, or the like.

As shown in FIG. 5, the first unit 50 includes a first semiconductor substrate 51 and a first element insulating layer 52 formed on the first semiconductor substrate 51.

The first semiconductor substrate 51 forms the unit back surface of the first unit 50. The unit back surface is the surface of the first unit 50 that faces the first die pad 81 (see FIG. 3). The unit back surface is bonded to the first die pad 81 by a conductive bonding material SD (see FIG. 3). The first semiconductor substrate 51 is made of a material including Si, for example. In the first embodiment, the first semiconductor substrate 51 is a Si substrate. The first semiconductor substrate 51 may be made of a wide-bandgap semiconductor or a compound semiconductor. A wide-bandgap semiconductor is a semiconductor substrate that has a bandgap of 2.0 eV or more. The wide-bandgap semiconductor may be silicon carbide (SiC). The compound semiconductor may be a III-V compound semiconductor. The compound semiconductor may include at least one of aluminum nitride (AlN), indium nitride (InN), gallium nitride (GaN), or gallium arsenide (GaAs).

The first element insulating layer 52 includes a first element surface 52S facing the third unit 70 (see FIG. 3) and a first element back surface 52R opposite to the first element surface 52S. The first element back surface 52R is in contact with the first semiconductor substrate 51. The first element surface 52S forms the unit surface of the first unit 50. The unit surface of the first unit 50 may be a surface that is in contact with the third unit 70, for example.

The first element insulating layer 52 includes multiple first insulating films 52P and multiple second insulating films 52Q. That is, the first element insulating layer 52 includes an insulator 52T, which is a laminate of the first insulating films 52P and the second insulating films 52Q. The insulator 52T is formed by alternately stacking the first insulating films 52P and the second insulating films 52Q in the Z-direction. As such, the Z-direction may also be considered as the thickness direction of the first element insulating layer 52.

Each first insulating film 52P is an etching stopper film, and is made of a material including at least one of silicon nitride (SiN), SiC, and nitrogen-doped silicon carbide (SiCN), for example. Also, the first insulating film 52P may have the function of preventing diffusion of Cu, for example. In other words, the first insulating film 52P may be a Cu-diffusion prevention film.

Each second insulating film 52Q is an interlayer insulating film, and is an oxide film made of a material including silicon oxide (SiO₂). The second insulating film 52Q has a greater thickness than the first insulating film 52P. The first insulating film 52P has a thickness of 50 nm or more and less than 1000 nm, for example. The second insulating film 52Q has a thickness of 500 nm or more and 5000 nm or less, for example. In the first embodiment, the first insulating film 52P has a thickness of about 300 nm, and the second insulating film 52Q has a thickness of about 2000 nm. In one example, the uppermost and lowermost insulating films of the insulator 52T are both second insulating films 52Q. To facilitate the understanding of the drawings, the ratio of the thickness of the first insulating film 52P to the thickness of the second insulating film 52Q in the drawings differs from the actual ratio of the thickness of the first insulating film 52P to the thickness of the second insulating film 52Q.

The first element insulating layer 52 includes a first protective film 53 and a first passivation film 54.

The first protective film 53 protects the insulator 52T, which is a laminate of the first insulating films 52P and the second insulating films 52Q. The first protective film 53 is formed on the insulator 52T. The first protective film 53 is made of a material including SiO₂, for example. In one example, the first protective film 53 is formed over the entire surface of the insulator 52T in plan view. The material of the first protective film 53 may be freely modified. The first protective film 53 may be made of a material including SiN.

The first passivation film 54 is a surface protective film of the first unit 50. The first passivation film 54 is formed on the first protective film 53. The first passivation film 54 forms the first element surface 52S of the first element insulating layer 52. The first passivation film 54 is made of a material including at least one of polyimide (PI), SiN, or SiO₂, for example. In one example, the first passivation film 54 is made of a material including SiO₂. In one example, the first passivation film 54 is formed over the entire surface of the first protective film 53 in plan view. The material of the first passivation film 54 may be freely modified. The first passivation film 54 may be made of the same material as the first protective film 53, or may be made of a material different from that of the first protective film 53.

The first coil 41 in the first unit 50 is formed in a spiral shape in plan view. As shown in FIG. 3, the first coil 41 is placed in the first unit 50 at a position closer to the second unit 60 in the X-direction. In one example, the first coil 41 is closer to the second unit 60 than the center of the first unit 50 is in the X-direction. More specifically, the first coil 41 is placed at one of the opposite end portions in the X-direction of the first unit 50 that is closer to the second unit 60.

The first coil 41 is embedded in the first element insulating layer 52 at a position spaced apart from the first element surface 52S in the Z-direction. Also, the first coil 41 is embedded in the first element insulating layer 52 at a position spaced apart from the first element back surface 52R in the Z-direction. In the first embodiment, the first coil 41 is placed closer to the first element surface 52S than the center of the first element insulating layer 52 is in the Z-direction. In one example, as shown in FIG. 5, the first coil 41 is provided in the second insulating film 52Q in the uppermost layer of the insulator 52T.

The first coil 41 is made of a material including one or more of Ti, TiN, Au, Ag, Cu, Al, and W appropriately selected. In the first embodiment, the first coil 41 is made of a material including Cu.

As indicated by the frame of the long-dash double-short-dash line in FIG. 4, the first circuit 20 formed in the first unit 50 is formed over a major part of the first unit 50 in plan view. As shown in FIG. 5, the first circuit 20 is provided on the first semiconductor substrate 51, for example. The first coil 41 is placed at a position overlapping the first circuit 20 in plan view. The transmitting circuit 21 of the first circuit 20 is placed at a position overlapping the first coil 41 in plan view. The size of the region in which the first circuit 20 is formed may be freely modified according to the function of the first circuit 20 and the like.

As shown in FIG. 2, the first pads 55 are placed at positions different from the third unit 70 in plan view. The first pads 55 are located on the opposite side of the second unit 60 with respect to the third unit 70 in the X-direction. The first pads 55 are placed at one of the opposite end portions of the first unit 50 in the X-direction that is farther from the second unit 60. It may also be considered that the first pads 55 are placed closer to the first leads 82 than to the third unit 70 in the X-direction. As shown in FIG. 5, each of the first pads 55 is exposed from the first element insulating layer 52 in the Z-direction.

The first unit 50 includes multiple first wiring lines 56A and 56B and multiple second wiring lines 57A to 57C. The first wiring lines 56A and 56B and the second wiring lines 57A to 57C are provided in the first element insulating layer 52. The first wiring lines 56A and 56B and the second wiring lines 57A to 57C are made of a material including one or more of Ti, TiN, Au, Ag, Cu, Al, and W appropriately selected, for example.

The first wiring line 56A and the second wiring line 57A are wiring lines that electrically connect the first pads 55 and the transmitting circuit 21 of the first circuit 20. The first wiring line 56A extends in the X-direction. The first wiring line 56A includes a first end portion overlapping with a first pad 55 and a second end portion overlapping with the transmitting circuit 21 in plan view. The first wiring line 56A is electrically connected to the transmitting circuit 21 at the second end portion. The first wiring line 56A is connected to the second wiring line 57A at the first end portion. The second wiring line 57A is wiring in which vias and wiring layers are alternately stacked in the Z-direction. The second wiring line 57A connects the first end portion of the first wiring line 56A and the first pad 55.

The first wiring line 56B and the second wiring lines 57B and 57C electrically connect the first coil 41 and the first circuit 20. The first wiring line 56B and the first wiring line 56A are placed on opposite sides of the transmitting circuit 21 in the X-direction. The first wiring line 56B extends in the X-direction. The first wiring line 56B includes a first end portion overlapping the inner end portion of the first coil 41 and a second end portion overlapping the transmitting circuit 21 in plan view. The first wiring line 56B is electrically connected to the transmitting circuit 21 at the second end portion. The first wiring line 56B is connected to the second wiring line 57B at the first end portion. The second wiring line 57B is wiring in which vias and wiring layers are alternately stacked in the Z-direction. The second wiring line 57B connects the first end portion of the first wiring line 56B and the inner end portion of the first coil 41.

The second wiring line 57C electrically connects the outer end portion of the first coil 41 to the transmitting circuit 21. As a result, both inner and outer end portions of the first coil 41 are electrically connected to the transmitting circuit 21. The second wiring line 57C is wiring in which vias and wiring layers are alternately stacked in the Z-direction. The second wiring line 57C is connected to the second end portion of the first wiring line 56A. In other words, the second wiring line 57C connects the outer end portion of the first coil 41 and the first wiring line 56A. The outer end portion of the first coil 41 is thus electrically connected to both the first pad 55 and the transmitting circuit 21. In this manner, the first circuit 20, the first coil 41, and the first pad 55 are electrically connected within the first unit 50, more specifically, within the first element insulating layer 52, by the first wiring lines 56A and 56B and the second wiring lines 57A to 57C.

### Second Unit

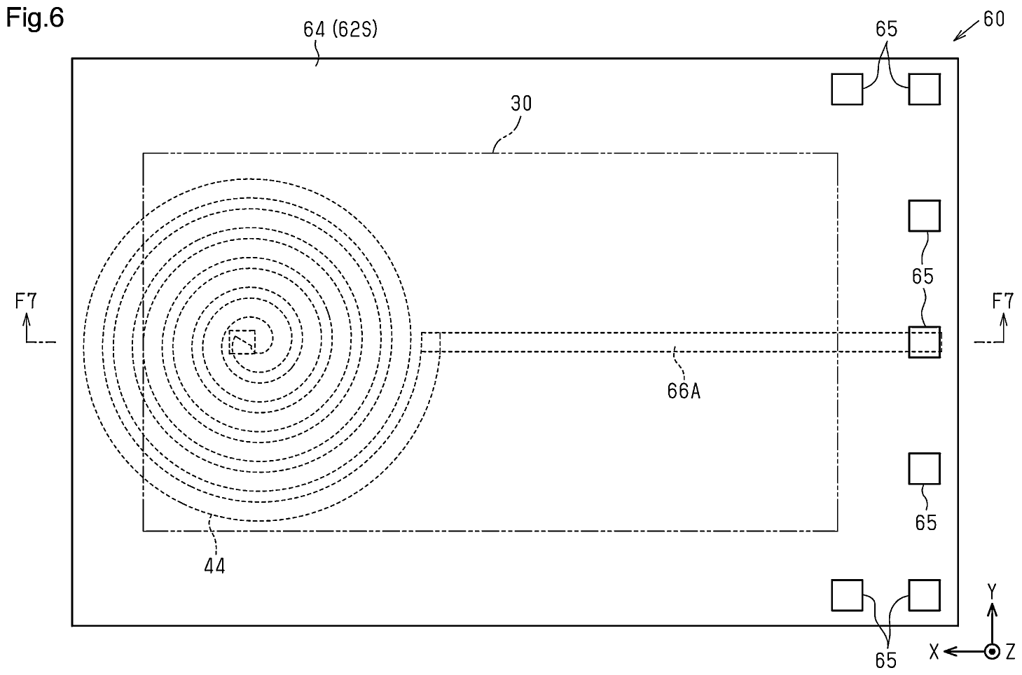

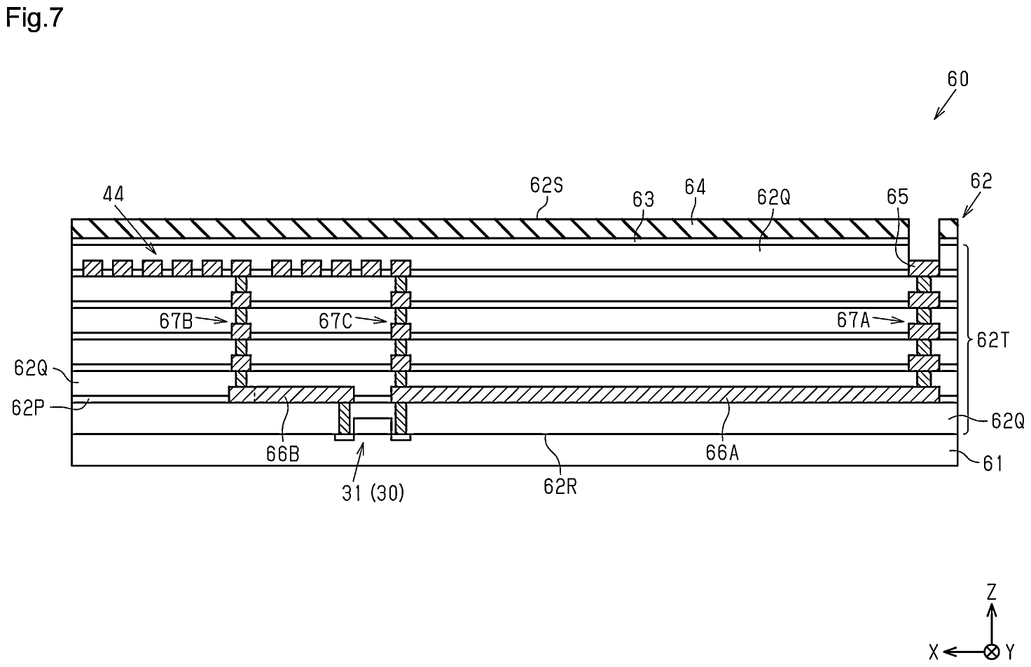

Referring to FIGS. 2, 3, 6, and 7, the configuration of the second unit 60 of the insulation chip 40P is now described. FIG. 6 schematically shows a planar structure of the second unit 60. FIG. 7 schematically shows a cross-sectional structure of the second unit 60 taken along line F7-F7 in FIG. 6. In FIG. 7, one transistor of the receiving circuit 31 is shown as the receiving circuit 31.

As shown in FIGS. 2 and 6, the second unit 60 includes multiple second pads 65. The second pads 65 are electrically connected to the second circuit 30. The second pads 65 are individually connected to the second leads 92 by wires W2. The second pads 65 are made of a material including one or more of Ti, TiN, Au, Ag, Cu, Al, and W appropriately selected. Each wire W2 is a bonding wire formed by a wire bonding device, and is made of a conductor including Au, Al, Cu, or the like.

As shown in FIG. 7, the second unit 60 includes a second semiconductor substrate 61 and a second element insulating layer 62 formed on the second semiconductor substrate 61. In the first embodiment, the configuration of the second semiconductor substrate 61 is the same as that of the first semiconductor substrate 51 (see FIG. 5). The dimension in the Z-direction (thickness) of the second semiconductor substrate 61 is the same as the dimension in the Z-direction (thickness) of the first semiconductor substrate 51. The dimension in the Z-direction (thickness) of the second element insulating layer 62 is the same as the dimension in the Z-direction (thickness) of the first element insulating layer 52 (see FIG. 5). The dimension in the Z-direction of the second unit 60 is therefore the same as the dimension in the Z-direction of the first unit 50.

The second element insulating layer 62 includes a second element surface 62S facing the third unit 70 (see FIG. 3) and a second element back surface 62R opposite to the second element surface 62S. The second element back surface 62R is in contact with the second semiconductor substrate 61. The second element surface 62S forms the unit surface of the second unit 60. The unit surface of the second unit 60 may be a surface that is in contact with the third unit 70, for example.

The second element insulating layer 62 includes multiple first insulating films 62P and multiple second insulating films 62Q. That is, the second element insulating layer 62 includes an insulator 62T, which is a laminate of the first insulating films 62P and the second insulating films 62Q. The insulator 62T is formed by alternately stacking the first insulating films 62P and second insulating films 62Q in the Z-direction. As such, the Z-direction may also be considered as the thickness direction of the second element insulating layer 62. The configuration of the first insulating film 62P is the same as the first insulating film 52P of the first element insulating layer 52 (see FIG. 5). The configuration of the second insulating film 62Q is the same as the second insulating film 52Q of the first element insulating layer 52 (see FIG. 5). The thickness of the first insulating film 62P is the same as the thickness of the first insulating film 52P, and the thickness of the second insulating film 62Q is the same as the thickness of the second insulating film 52Q.

The second element insulating layer 62 includes a second protective film 63 and a second passivation film 64.

The second protective film 63 protects the insulator 62T. The second protective film 63 is formed on the insulator 62T. The second protective film 63 is made of a material including SiO₂, for example. In one example, the second protective film 63 is formed over the entire surface of the insulator 62T in plan view. The material of the second protective film 63 may be freely modified. In one example, the second protective film 63 may be made of a material including SiN.

The second passivation film 64 is a surface protective film of the second unit 60. The second passivation film 64 is formed on the second protective film 63. The second passivation film 64 forms the second element surface 62S of the second element insulating layer 62. The second passivation film 64 is made of a material including at least one of PI, SiN, or SiO₂, for example. In one example, the second passivation film 64 is made of a material including SiO₂. In one example, the second passivation film 64 is formed over the entire surface of the second protective film 63 in plan view. The material of the second passivation film 64 may be freely modified. The second passivation film 64 may be made of the same material as the second protective film 63, or may be made of a material different from that of the second protective film 63.

The fourth coil 44 in the second unit 60 is formed in a spiral shape in plan view. As shown in FIG. 3, the fourth coil 44 is placed in the second unit 60 at a position closer to the first unit 50 in the X-direction. In one example, the fourth coil 44 is placed closer to the first unit 50 than the center of the second unit 60 is in the X-direction. More specifically, the fourth coil 44 is placed at one of the opposite ends in the X-direction of the second unit 60 that is closer to the first unit 50.

The fourth coil 44 is embedded in the second element insulating layer 62 at a position spaced apart from the second element surface 62S in the Z-direction. Also, the fourth coil 44 is embedded in the second element insulating layer 62 at a position spaced apart from the second element back surface 62R in the Z-direction. In the first embodiment, the fourth coil 44 is placed closer to the second element surface 62S than the center of the second element insulating layer 62 is in the Z-direction. In one example, the fourth coil 44 is provided in the second insulating film 62Q in the uppermost layer of the insulator 62T. In other words, the fourth coil 44 is placed at the same position as the first coil 41 in the Z-direction.

The fourth coil 44 is made of a material including one or more of Ti, TiN, Au, Ag, Cu, Al, and W appropriately selected. In one example, the fourth coil 44 may be made of the same material as the first coil 41. In the first embodiment, the fourth coil 44 is made of a material including Cu.

As indicated by the frame of the long-dash double-short-dash line in FIG. 6, the second circuit 30 formed in the second unit 60 is formed over a major part of the second unit 60 in plan view. As shown in FIG. 7, the second circuit 30 is provided on the second semiconductor substrate 61, for example. The fourth coil 44 is placed at a position overlapping the second circuit 30 in plan view. The receiving circuit 31 of the second circuit 30 is placed at a position overlapping the fourth coil 44 in plan view.

The second pads 65 are placed at positions different from the third unit 70 in plan view. The second pads 65 are located on the opposite side of the first unit 50 with respect to the third unit 70 in the X-direction. The second pads 65 are placed at one of the opposite ends of the second unit 60 in the X-direction that is farther from the first unit 50. It may also be considered that the second pads 65 are placed closer to the second leads 92 than to the third unit 70 in the X-direction. Each second pad 65 is exposed from the second element insulating layer 62 in the Z-direction.

The second unit 60 includes multiple first wiring lines 66A and 66B and multiple second wiring lines 67A to 67C. The first wiring lines 66A and 66B and the second wiring lines 67A to 67C are provided in the second element insulating layer 62. The first wiring lines 66A and 66B and the second wiring lines 67A to 67C are made of a material including one or more of Ti, TiN, Au, Ag, Cu, Al, and W appropriately selected, for example.

The first wiring line 66A and the second wiring line 67A are wiring lines that electrically connect the second pads 65 and the receiving circuit 31 of the second circuit 30. The first wiring line 66A extends in the X-direction. The first wiring line 66A includes a first end portion overlapping a second pad 65 and a second end portion overlapping the receiving circuit 31 in plan view. The first wiring line 66A is electrically connected to the receiving circuit 31 at the second end portion. The first wiring line 66A is connected to the second wiring line 67A at the first end portion. The second wiring line 67A is wiring in which vias and wiring layers are alternately stacked in the Z-direction. The second wiring line 67A connects the first end portion of the first wiring line 66A and the second pad 65.

The first wiring line 66B and the second wiring lines 67B and 67C electrically connect the fourth coil 44 and the second circuit 30. The first wiring line 66B and the first wiring line 66A are placed on opposite sides of the receiving circuit 31 in the X-direction. The first wiring line 66B extends in the X-direction. The first wiring line 66B includes a first end portion overlapping the inner end portion of the fourth coil 44 and a second end portion overlapping the receiving circuit 31 in plan view. The first wiring line 66B is electrically connected to the receiving circuit 31 at the second end portion. The first wiring line 66B is connected to the second wiring line 67B at the first end portion. The second wiring line 67B is wiring in which vias and wiring layers are alternately stacked in the Z-direction. The second wiring line 67B connects the first end portion of the first wiring line 66B and the inner end portion of the fourth coil 44.

The second wiring line 67C electrically connects the outer end portion of the fourth coil 44 to the receiving circuit 31. As a result, both inner and outer end portions of the fourth coil 44 are electrically connected to the receiving circuit 31. The second wiring line 67C is wiring in which vias and wiring layers are alternately stacked in the Z-direction. The second wiring line 67C is connected to the second end portion of the first wiring line 66A. In other words, the second wiring line 67C connects the outer end portion of the fourth coil 44 and the first wiring line 66A. The outer end portion of the fourth coil 44 is thus electrically connected to both the second pad 65 and the receiving circuit 31. In this manner, the second circuit 30, the fourth coil 44, and the second pads 65 are electrically connected within the second unit 60, more specifically, within the second element insulating layer 62, by the first wiring lines 66A and 66B and the second wiring line 67A to 67C.

### Third Unit

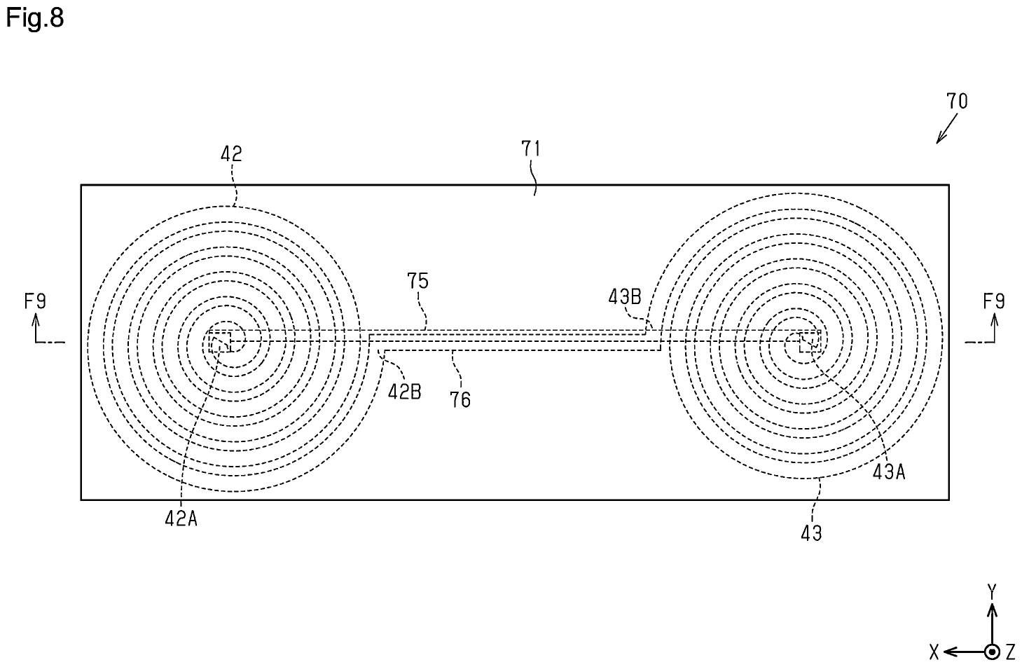

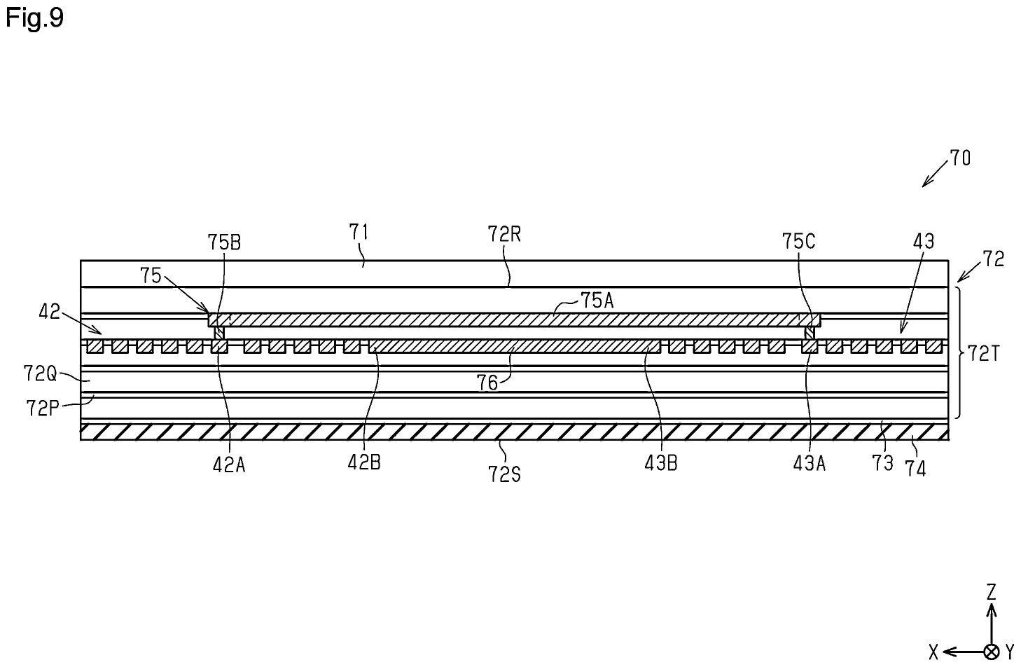

Referring to FIGS. 2, 3, 8, and 9, the configuration of the third unit 70 of the insulation chip 40P is now described. FIG. 8 schematically shows a planar structure of the third unit 70. FIG. 9 schematically shows a cross-sectional structure of the third unit 70 taken along line F9-F9 in FIG. 8.

As shown in FIG. 3, the third unit 70 is electrically insulated from the first unit 50 and the second unit 60. The third unit 70 is electrically insulated also from the first and second lead frames 80 and 90. In this manner, the third unit 70 is in an electrically floating state.

As shown in FIG. 9, the third unit 70 includes a third semiconductor substrate 71 and a third element insulating layer 72 formed on the third semiconductor substrate 71. The third element insulating layer 72 is located below the third semiconductor substrate 71. In other words, the third element insulating layer 72 is located closer to the first and second units 50 and 60 (refer to FIG. 3) than the third semiconductor substrate 71 is. The third semiconductor substrate 71 has the same configuration as the first semiconductor substrate 51 (see FIG. 5). The dimension in the Z-direction (thickness) of the third semiconductor substrate 71 may be the same as the dimension in the Z-direction (thickness) of the first semiconductor substrate 51, for example. The dimension in the Z-direction (thickness) of the third element insulating layer 72 may be less than the dimension in the Z-direction (thickness) of the first element insulating layer 52 (see FIG. 5), for example. Accordingly, the dimension in the Z-direction of the third unit 70 may be less than the dimension in the Z-direction of the first unit 50.

The dimension in the Z-direction of the third semiconductor substrate 71 may be freely modified. In one example, the dimension in the Z-direction of the third semiconductor substrate 71 may be less than the dimension in the Z-direction of the first semiconductor substrate 51. In one example, the dimension in the Z-direction of the third element insulating layer 72 may be freely modified. In one example, the dimension in the Z-direction of the third element insulating layer 72 may be greater than or equal to the dimension in the Z-direction of the first element insulating layer 52.

The third element insulating layer 72 includes a third element surface 72S facing the first unit 50 and the second unit 60 (see FIG. 3), and a third element back surface 72R opposite to the third element surface 72S. The third element back surface 72R is in contact with the third semiconductor substrate 71. The third element surface 72S forms the unit surface of the third unit 70. The unit surface of the third unit 70 may be a surface that is in contact with both the unit surface of the first unit 50 and the unit surface of the second unit 60, for example.

The third element insulating layer 72 includes multiple first insulating films 72P and multiple second insulating films 72Q. That is, the third element insulating layer 72 includes an insulator 72T, which is a laminate of the first insulating films 72P and the second insulating films 72Q. The insulator 72T is formed by alternately stacking the first insulating films 72P and the second insulating films 72Q in the Z-direction. As such, the Z-direction may also be considered as the thickness direction of the third element insulating layer 72. The configuration of the first insulating film 72P is the same as the first insulating film 52P of the first element insulating layer 52 (see FIG. 5). The configuration of the second insulating film 72Q is the same as the second insulating film 52Q of the first element insulating layer 52 (see FIG. 5). The thickness of the first insulating film 72P is the same as the thickness of the first insulating film 52P, and the thickness of the second insulating film 72Q is the same as the thickness of the second insulating film 52Q.

The third element insulating layer 72 includes a third protective film 73 and a third passivation film 74.

The third protective film 73 protects the insulator 72T, which is a laminate of the first insulating films 72P and the second insulating films 72Q. The third protective film 73 is formed on the insulator 72T. The third protective film 73 is made of a material including SiO₂. In one example, the third protective film 73 is formed on the entire surface of the insulator 72T in plan view. The material of the third protective film 73 may be freely modified. In one example, the third protective film 73 may be made of a material including SiN.

The third passivation film 74 is a surface protective film for the third unit 70. The third passivation film 74 is formed on the third protective film 73. The third passivation film 74 forms the third element surface 72S of the third element insulating layer 72. The third passivation film 74 is made of a material including at least one of PI, SiN, or SiO₂, for example. In one example, the third passivation film 74 is made of a material including SiO₂. In one example, the third passivation film 74 is formed over the entire surface of the third protective film 73 in plan view. The material of the third passivation film 74 may be freely modified. The third passivation film 74 may be made of the same material as the third protective film 73, or may be made of a material different from that of the third protective film 73.

Both the second and third coils 42 and 43 in the third unit 70 are formed in a spiral shape in plan view. The second and third coils 42 and 43 are arranged to be spaced apart from each other in the X-direction and are electrically connected to each other. Also, the second and third coils 42 and 43 are placed at the same position in the Y-direction. The number of turns of the second and third coils 42 and 43 may be freely modified. In one example, the number of turns of the second coil 42 may be the same as the number of turns of the first coil 41 (see FIG. 3). In one example, the number of turns of the second coil 42 may be less than the number of turns of the first coil 41. In one example, the number of turns of the second coil 42 may be greater than the number of turns of the first coil 41. In one example, the number of turns of the third coil 43 may be the same as the number of turns of the fourth coil 44 (see FIG. 3). In one example, the number of turns of the third coil 43 may be less than the number of turns of the fourth coil 44. In one example, the number of turns of the third coil 43 may be greater than the number of turns of the fourth coil 44.

Both the second and third coils 42 and 43 are embedded in the third element insulating layer 72 at positions spaced apart from the third element surface 72S in the Z-direction. Both the second and third coils 42 and 43 are embedded in the third element insulating layer 72 at positions spaced apart from the third element back surface 72R in the Z-direction. In one example, the second and third coils 42 and 43 are placed at the same position in the Z-direction. In the first embodiment, both the second and third coils 42 and 43 are placed closer to the third element back surface 72R than the center of the third element insulating layer 72 is in the Z-direction.

As shown in FIG. 8, the second coil 42 includes a first coil end portion 42A and a second coil end portion 42B. The first coil end portion 42A is provided inside the second coil 42. The second coil end portion 42B is provided outside the second coil 42.

The third coil 43 includes a third coil end portion 43A and a fourth coil end portion 43B. The third coil end portion 43A is provided inside the third coil 43. The fourth coil end portion 43B is provided outside the third coil 43.

Both the second and third coils 42 and 43 are made of a material including one or more of Ti, TiN, Au, Ag, Cu, Al, and W appropriately selected. In one example, both the second and third coils 42 and 43 may be made of the same material as the first coil 41. In one example, both the second and third coils 42 and 43 may be made of the same material as the fourth coil 44. In the first embodiment, both the second and third coils 42 and 43 are made of a material including Cu.

The third unit 70 includes a first connection wiring line 75 and a second connection wiring line 76, which electrically connect the second coil 42 and the third coil 43.

As shown in FIG. 9, the first connection wiring line 75 connects the first coil end portion 42A of the second coil 42 and the third coil end portion 43A of the third coil 43. The first connection wiring line 75 includes a first wiring portion 75A, which extends in the X-direction, a first via 75B, which connects the first wiring portion 75A and the first coil end portion 42A, and a second via 75C, which connects the first wiring portion 75A and the third coil end portion 43A. In one example, the first wiring portion 75A is placed closer to the third element back surface 72R than the second and third coils 42 and 43 are in the Z-direction. The first wiring portion 75A extends in the X-direction in plan view.

The second connection wiring line 76 connects the second coil end portion 42B of the second coil 42 and the fourth coil end portion 43B of the third coil 43. The second connection wiring line 76 is placed at the same position as the second and third coils 42 and 43 in the Z-direction. The second connection wiring line 76 extends in the X-direction. In one example, the second connection wiring line 76 is placed at a position overlapping the first connection wiring line 75 in plan view. In FIG. 8, to facilitate the understanding of the figure, the second connection wiring line 76 is shown offset from the first connection wiring line 75 in the Y-direction in plan view. However, the position of the second connection wiring line 76 in the Y-direction is actually the same as the position of the first connection wiring line 75 in the Y-direction in plan view.

For example, the first connection wiring line 75 and the second connection wiring line 76 are made of a material including one or more of Ti, TiN, Au, Ag, Cu, Al, and W appropriately selected. In one example, both the first connection wiring line 75 and the second connection wiring line 76 may be made of the same material as the second and third coils 42 and 43. In one example, both the first connection wiring line 75 and the second connection wiring line 76 may be made of a material different from that of the second and third coils 42 and 43.

### Configuration in Unit Arrangement State

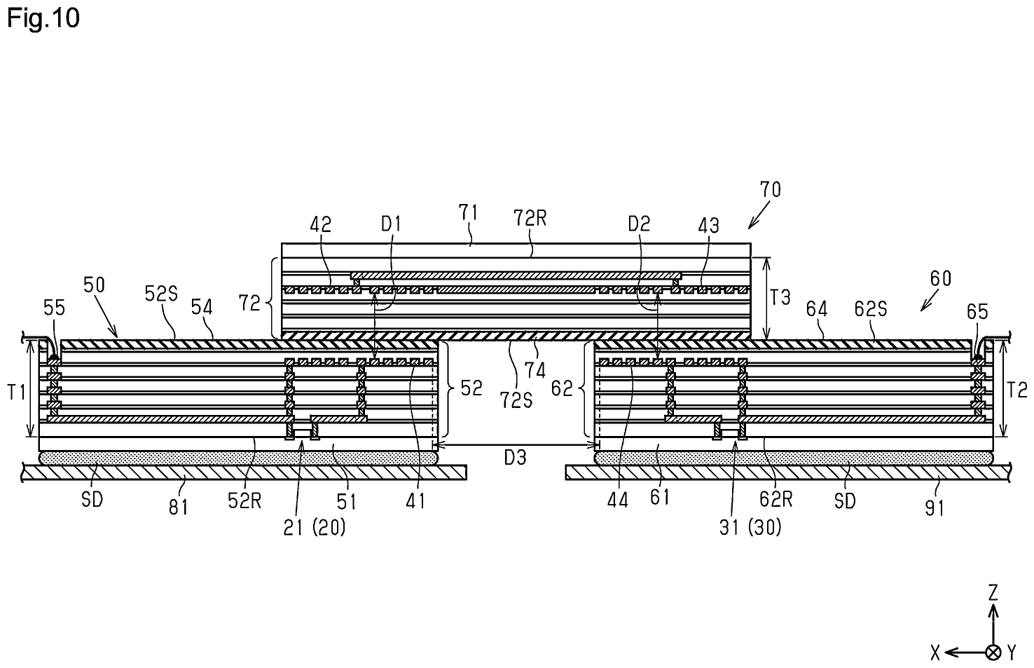

Referring to FIG. 10, the configuration is now described in a state in which the third element insulating layer 72 of the third unit 70 is placed on both the first element insulating layer 52 of the first unit 50 and the second element insulating layer 62 of the second unit 60 (hereinafter referred to as a “unit arrangement state”). FIG. 10 schematically shows a cross-sectional structure of the first unit 50, the second unit 60, and the third unit 70 in the unit arrangement state.

As shown in FIG. 10, in the first embodiment, the third element insulating layer 72 is in contact with both the first and second element insulating layers 52 and 62 in the unit arrangement state. More specifically, in the unit arrangement state, the third element surface 72S of the third element insulating layer 72 is in contact with both the first element surface 52S of the first element insulating layer 52 and the second element surface 62S of the second element insulating layer 62. That is, the third passivation film 74 of the third element insulating layer 72 is in contact with both the first passivation film 54 of the first element insulating layer 52 and the second passivation film 64 of the second element insulating layer 62. On the other hand, in the first embodiment, the third element insulating layer 72 is not bonded to either the first element insulating layer 52 or the second element insulating layer 62.

In the unit arrangement state, the first coil 41 of the first unit 50 and the second coil 42 of the third unit 70 are placed to face each other in the Z-direction. In the unit arrangement state, the fourth coil 44 of the second unit 60 and the third coil 43 of the third unit 70 are placed to face each other in the Z-direction.

In the first embodiment, the distance D1 between the first and second coils 41 and 42 in the Z-direction is less than the thickness T1 of the first element insulating layer 52. The distance D1 is also less than the thickness T3 of the third element insulating layer 72. Furthermore, the distance D2 between the third and fourth coils 43 and 44 in the Z-direction is less than the thickness T2 of the second element insulating layer 62. The distance D2 is also less than the thickness T3 of the third element insulating layer 72. In one example, the distance D2 is equal to the distance D1.

The distance D3 between the first and fourth coils 41 and 44 in the X-direction is greater than or equal to the distance D1 between the first and second coils 41 and 42 in the Z-direction, and is greater than or equal to the distance D2 between the third and fourth coils 43 and 44 in the Z-direction. In the first embodiment, the distance D3 is greater than the distance D1 and greater than the distance D2. In one example, the distance D3 is greater than the thickness Ti of the first element insulating layer 52. In one example, the distance D3 is greater than the thickness T2 of the second element insulating layer 62. The distance D3 is greater than the thickness T3 of the third element insulating layer 72.

The minimum distance between the first pads 55 and the second coil 42 is greater than the distance D1 between the first and second coils 41 and 42. The distance D1 between the first and second coils 41 and 42 is the distance in the Z-direction. The minimum distance between the second pads 65 and the third coil 43 is greater than the distance D2 between the third and fourth coils 43 and 44. The distance D2 between the third and fourth coils 43 and 44 is the distance in the Z-direction.

### Semiconductor Device Manufacturing Method

An example of a method for manufacturing the semiconductor device 10 of the first embodiment is now described. In the following description, refer to FIGS. 1 to 9 for reference numerals relating to the components of the semiconductor device 10.

The method for manufacturing the semiconductor device 10 includes the steps of preparing a first unit 50, preparing a second unit 60, preparing a third unit 70, and preparing a first lead frame 80 and a second lead frame 90.

The step of preparing the first unit 50 includes the step of forming a first element insulating layer 52, a first coil 41, multiple first pads 55, multiple first wiring lines 56A and 56B, and multiple second wiring lines 57A to 57C on a first semiconductor substrate 51 on which the first circuit 20 is formed. The first coil 41, the first pads 55, the first wiring lines 56A and 56B, and the second wiring lines 57A to 57C are formed by etching and sputtering using a metal mask during the process of stacking the first and second insulating films 52P and 52Q of the first element insulating layer 52.

The step of preparing the second unit 60 includes the step of forming a second element insulating layer 62, a fourth coil 44, multiple second pads 65, multiple first wiring lines 66A and 66B, and multiple second wiring lines 67A to 67C on a second semiconductor substrate 61 on which the second circuit 30 is formed. The fourth coil 44, the second pads 65, the first wiring lines 66A and 66B, and the second wiring lines 67A to 67C are formed by etching and sputtering using a metal mask during the process of stacking the first and second insulating films 62P and 62Q of the second element insulating layer 62.

The step of preparing the third unit 70 includes the step of forming a third element insulating layer 72, a second coil 42, a third coil 43, a first connection wiring line 75, a second connection wiring line 76 on a third semiconductor substrate 71. The second coil 42, the third coil 43, the first connection wiring line 75, and the second connection wiring line 76 are formed by etching and sputtering using a metal mask during the process of stacking the first and second insulating films 72P and 72Q of the third element insulating layer 72.

The method for manufacturing the semiconductor device 10 includes the step of mounting the first unit 50 on the first die pad 81 of the first lead frame 80, and the step of mounting the second unit 60 on the second die pad 91 of the second lead frame 90.

In the process of mounting the first unit 50 on the first die pad 81, a conductive bonding material SD is first applied to the first die pad 81. The first unit 50 is then placed on the conductive bonding material SD. Then, the conductive bonding material SD is melted and solidified to bond the first unit 50 to the first die pad 81.

In the step of mounting the second unit 60 on the second die pad 91, a conductive bonding material SD is first applied to the second die pad 91. The second unit 60 is then placed on the conductive bonding material SD. Then, the conductive bonding material SD is melted and solidified to bond the second unit 60 to the second die pad 91. The conductive bonding material SD applied to the first die pad 81 and the conductive bonding material SD applied to the second die pad 91 may be melted and solidified at the same time.

The method for manufacturing the semiconductor device 10 includes the steps of forming multiple wires W1 and multiple wires W2. The wires W1 are formed to individually connect the first pads 55 to the first leads 82 of the first lead frame 80 using a wire bonding device. The wires W2 are formed to individually connect the second pads 65 to the second leads 92 of the second lead frame 90 using a wire bonding device.

The method for manufacturing the semiconductor device 10 includes the step of arranging the third unit 70 on the first unit 50 and on the second unit 60 so as to extend over the space between the first and second units 50 and 60 in the X-direction. The third unit 70 is on the first and second units 50 and 60, so that the third element insulating layer 72 of the third unit 70 is in contact with the first element insulating layer 52 of the first unit 50 and the second element insulating layer 62 of the second unit 60.

The method for manufacturing the semiconductor device 10 includes the step of forming the sealing plastic 100. This step forms the sealing plastic 100 by transfer molding. The sealing plastic 100 thus seals the first unit 50, the second unit 60, the third unit 70, the first die pads 81, the second die pads 91, and the wires W1 and W2. Through the above steps, the semiconductor device 10 is manufactured.

### Operation of First Embodiment

Operation of the semiconductor device 10 of the first embodiment is now described.

The semiconductor device 10 includes the third unit 70, which includes the third element insulating layer 72 in which the second coil 42 and the third coil 43 are embedded, in addition to the first unit 50, which includes the first element insulating layer 52 in which the first coil 41 is embedded, and the second unit 60, which includes the second element insulating layer 62 in which the fourth coil 44 is embedded. In the unit arrangement state, the first coil 41 and the second coil 42 are opposed to each other in the Z-direction, and the third coil 43 and the fourth coil 44 are opposed to each other. As such, both the first and third element insulating layers 52 and 72 are interposed between the first and second coils 41 and 42 in the Z-direction, and both the second and third element insulating layers 62 and 72 are interposed between the third and fourth coils 43 and 44 in the Z-direction.

In this manner, the element insulating layer between the first and second coils 41 and 42 is a laminate structure of the first element insulating layer 52 formed on the first semiconductor substrate 51 and the third element insulating layer 72 formed on the third semiconductor substrate 71. This allows both the thickness T1 of the first element insulating layer 52 and the thickness T3 of the third element insulating layer 72 to be thinner than that in a configuration in which the element insulating layer between the first and second coils 41 and 42 is an element insulating layer formed on a single semiconductor substrate. As a result, the first and third semiconductor substrates 51 and 71 resist warping. Likewise, the element insulating layer between the third and fourth coils 43 and 44 is a laminate structure of the second element insulating layer 62 formed on the second semiconductor substrate 61 and the third element insulating layer 72 formed on the third semiconductor substrate 71. This allows both the thickness T2 of the second element insulating layer 62 and the thickness T3 of the third element insulating layer 72 to be thinner than that in a configuration in which the element insulating layer between the first and second coils 43 and 44 is an element insulating layer formed on a single semiconductor substrate. As a result, both the second and third semiconductor substrates 61 and 71 resist warping.

### Advantages of First Embodiment

The semiconductor device 10 of the first embodiment has the following advantages.

(1-1) The semiconductor device 10 includes the first unit 50 and the second unit 60, which are arranged to be spaced apart from each other in the X-direction, and the third unit 70, which is placed on the first unit 50 and on the second unit 60 so as to extend over the space between the first and second units 50 and 60 in the X-direction. The first unit 50 includes the first semiconductor substrate 51, the first element insulating layer 52, which includes the first element surface 52S facing the third unit 70 and the first element back surface 52R opposite to the first element surface 52S and in which the first element back surface 52R is in contact with the first semiconductor substrate 51, and the first coil 41 embedded in the first element insulating layer 52 at a position spaced apart from the first element surface 52S in the Z-direction. The second unit 60 includes the second semiconductor substrate 61, the second element insulating layer 62, which includes the second element surface 62S facing the third unit 70 and the second element back surface 62R opposite to the second element surface 62S and in which the second element back surface 62R is in contact with the second semiconductor substrate 61, and the fourth coil 44 embedded in the second element insulating layer 62 at a position spaced apart from the second element surface 62S in the Z-direction. The third unit 70 includes the third semiconductor substrate 71, the third element insulating layer 72, which includes the third element surface 72S and the third element back surface 72R opposite to the third element surface 72S and in which the third element back surface 72R is in contact with the third semiconductor substrate 71, and the second coil 42 and the third coil 43, which are embedded in the third element insulating layer 72 at positions spaced apart from the third element surface 72S in the Z-direction, arranged to be spaced apart from each other in the X-direction, and electrically connected to each other. In the unit arrangement state in which the third element insulating layer 72 of the third unit 70 is arranged on both the first element insulating layer 52 of the first unit 50 and the second element insulating layer 62 of the second unit 60, the first coil 41 and the second coil 42 are placed to face each other in the Z-direction, and the third coil 43 and the fourth coil 44 are placed to face each other in the Z-direction.

According to this configuration, the area between the first and second coils 41 and 42 in the Z-direction is formed by a laminate structure of the first and third element insulating layers 52 and 72. This allows both the thicknesses T2 and T3 of the first and third element insulating layers 52 and 72 to be thinner than that in a configuration in which the area between the first and second coils 41 and 42 in the Z-direction is an element insulating layer formed on a single semiconductor substrate. As a result, the first and third semiconductor substrates 51 and 71 resist warping.

Also, the area between the third and fourth coils 43 and 44 in the Z-direction is formed by a laminate of the second and third element insulating layers 62 and 72. This allows both the thicknesses T2 and T3 of the second and third element insulating layers 62 and 72 to be thinner than that in a configuration in which the area between the third and fourth coils 43 and 44 in the Z-direction is a single element insulating layer. As a result, the second and third semiconductor substrates 61 and 71 resist warping.

(1-2) The first unit 50 includes the first pads 55 electrically connected to the first coil 41. Each first pad 55 is located on the opposite side of the second unit 60 with respect to the third unit 70 in the X-direction. The first pad 55 is exposed from the first element insulating layer 52 in the Z-direction.

According to this configuration, since the first pad 55 is exposed from the first element insulating layer 52 at a position away from the third unit 70, the wires W1 can be easily connected to the first pad 55.

(1-3) The first unit 50 includes the first wiring line 56A electrically connected to the first coil 41, and the second wiring line 57A connecting the first wiring line 56A and the first pad 55.

According to this configuration, since the first pad 55 is provided in the first element insulating layer 52, the dimension of the second wiring line 57A in the Z-direction can be reduced. In other words, as compared with a configuration in which the area between the first and second coils 41 and 42 is an element insulating layer formed on a single semiconductor substrate, the number of insulating films of the first element insulating layer 52 for forming the second wiring line 57A can be reduced. This reduces the number of metal masks for forming the second wiring line 57A. As a result, the manufacturing cost of the first unit 50 can be reduced.

(1-4) The second unit 60 includes the second pads 65 electrically connected to the fourth coil 44. Each second pad 65 is located on the opposite side of the first unit 50 with respect to the third unit 70 in the X-direction. The second pad 65 is exposed from the second element insulating layer 62 in the Z-direction.

According to this configuration, since the second pad 65 is exposed from the second element insulating layer 62 at a position away from the third unit 70, the wires W2 can be easily connected to the second pad 65.

(1-5) The second unit 60 includes the first wiring line 66A electrically connected to the fourth coil 44, and the second wiring line 67A connecting the first wiring line 66A and the second pad 65.

According to this configuration, since the second pad 65 is provided in the second element insulating layer 62, the dimension of the second wiring line 67A in the Z-direction can be reduced. In other words, as compared with a configuration in which the area between the third and fourth coils 43 and 44 is an element insulating layer formed on a single semiconductor substrate, the number of insulating films of the second element insulating layer 62 for forming the second wiring line 67A can be reduced. This reduces the number of metal masks for forming the second wiring line 67A. As a result, the manufacturing cost of the second unit 60 can be reduced.

(1-6) The third element surface 72S of the third element insulating layer 72 of the third unit 70 is in contact with both the first element surface 52S of the first element insulating layer 52 of the first unit 50 and the second element surface 62S of the second element insulating layer 62 of the second unit 60. The second and third coils 42 and 43 of the third unit 70 are in an electrically floating state.

According to this configuration, the third unit 70 is merely placed relative to the first unit 50 and the second unit 60, and the third unit 70 is not bonded to the first unit 50 or the second unit 60. As such, there is a risk that the position of the third unit 70 may be misaligned with the first unit 50 and the second unit 60 during resin molding.

Since the second and third coils 42 and 43 of the third unit 70 are in an electrically floating state, the third unit 70 is not electrically connected to the first unit 50 or the second unit 60. This allows the position of the third unit 70 to be misaligned with the first and second units 50 and 60 during resin molding, provided that the misalignment is within a range that enables magnetic coupling between the first and second coils 41 and 42 and within a range that enables magnetic coupling between the third and fourth coils 43 and 44. This eliminates the need for the third unit 70 to be positioned with high accuracy relative to the first and second units 50 and 60. The semiconductor device 10 can therefore be manufactured easily.

(1-7) The first unit 50 includes the first circuit 20. The second unit 60 includes the second circuit 30.

According to this configuration, as compared with a configuration that includes a dedicated semiconductor chip for the first circuit 20 and a dedicated semiconductor chip for the second circuit 30 separately from the first to third units 50, 60, and 70, the number of semiconductor chips can be reduced. This allows for a smaller semiconductor device 10 and a lower cost.

(1-8) The first circuit 20 includes the transmitting circuit 21 electrically connected to the first coil 41. The second circuit 30 includes the receiving circuit 31 electrically connected to the fourth coil 44. The transmitting circuit 21 is placed at a position overlapping the first coil 41 in plan view. The receiving circuit 31 is placed at a position overlapping the fourth coil 44 in plan view.

According to this configuration, the length of the conductive path between the first coil 41 and the transmitting circuit 21 can be shortened. This allows the inductance caused by the length of this conductive path to be reduced. Additionally, the length of the conductive path between the fourth coil 44 and the receiving circuit 31 can be shortened. This allows the inductance caused by the length of this conductive path to be reduced.

(1-9) The distance D3 between the first and fourth coils 41 and 44 in the X-direction is greater than or equal to the distance D1 between the first and second coils 41 and 42 in the Z-direction, and is greater than or equal to the distance D2 between the third and fourth coils 43 and 44 in the Z-direction. According to this configuration, the withstand voltage of the semiconductor device 10 is less likely to be reduced as compared with a configuration in which the distance D3 is less than the distances D1 and D2.

(1-10) The first unit 50 including the first coil 41, the second unit 60 including the fourth coil 44, and the third unit 70 including the second coil 42 and the third coil 43 are provided separately.

According to this configuration, by changing the number of insulating films in the third element insulating layer 72 of the third unit 70, multiple types of semiconductor devices 10 with different withstand voltages can be manufactured. Thus, it is easy to provide a variety of semiconductor devices 10 with different withstand voltages.

(1-11) The first coil 41 is placed closer to the second unit 60 than the center of the first element insulating layer 52 is in the X-direction. The fourth coil 44 is placed closer to the first unit 50 than the center of the second element insulating layer 62 is in the X-direction.

According to this configuration, the shorter distance D3 in the X-direction between the first and fourth coils 41 and 44 shortens the distance in the X-direction between the second coil 42, which is placed to face the first coil 41 in the Z-direction, and the third coil 43, which is placed to face the fourth coil 44 in the Z-direction. This allows the third unit 70 to be smaller in size in the X-direction.

### Second Embodiment

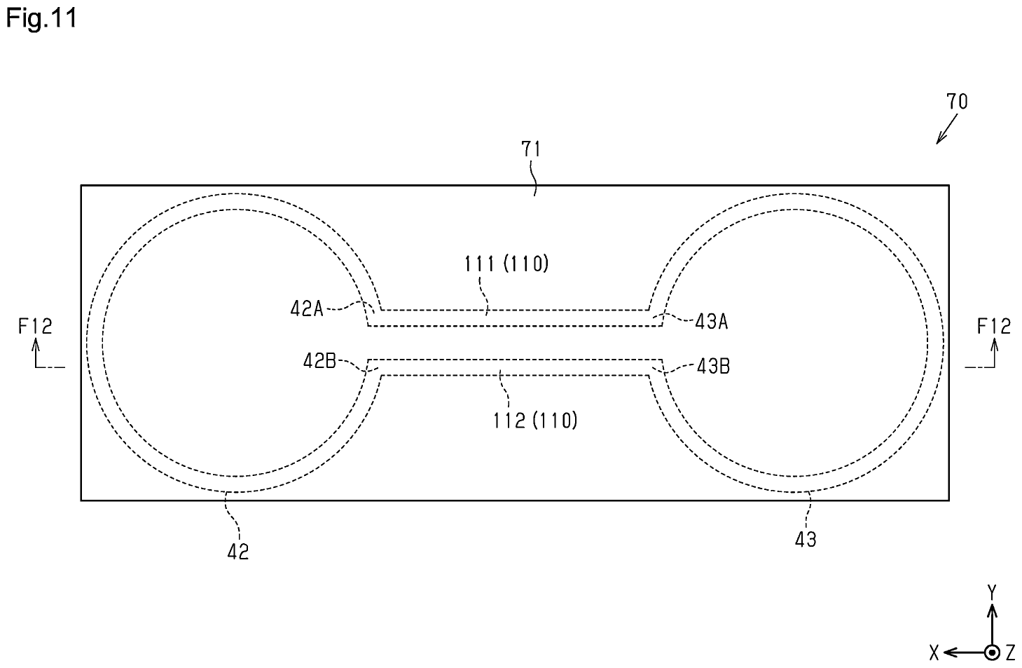

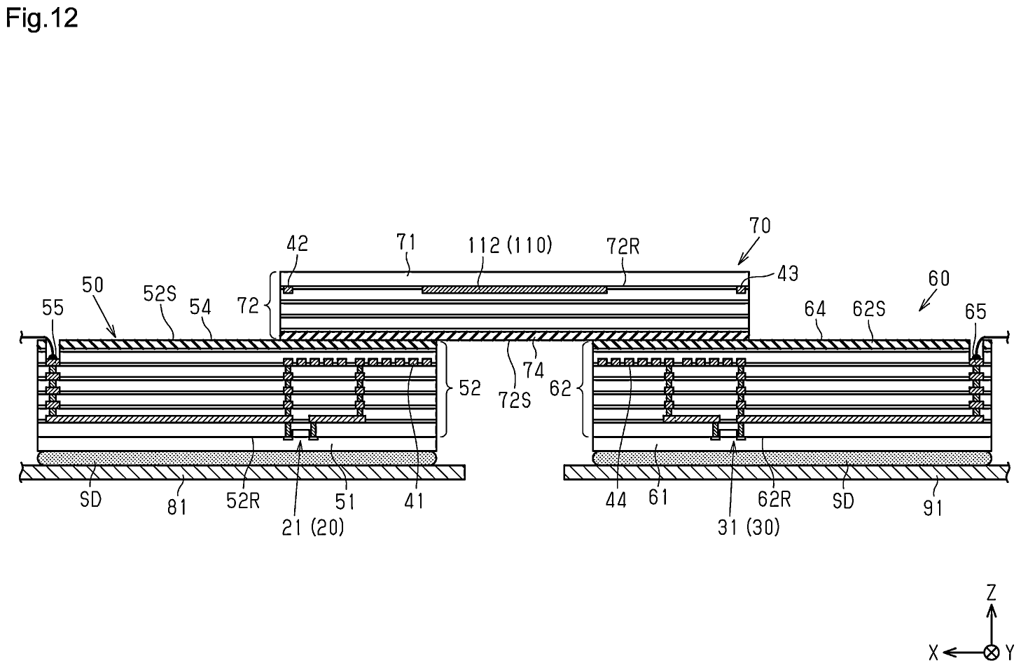

Referring to FIGS. 11 and 12, a semiconductor device 10 according to a second embodiment is now described. The semiconductor device 10 of the second embodiment differs from the semiconductor device 10 of the first embodiment mainly in the configurations of the third coil 43 and the fourth coil 44 of the third unit 70. In the following description, the differences from the first embodiment are described in detail, and components common to the first embodiment are given the same reference numerals and descriptions thereof are omitted. FIG. 11 schematically shows a planar structure of the third unit 70. FIG. 12 schematically shows a cross-sectional structure of the semiconductor device 10 taken along line F12-F12 in FIG. 11.

As shown in FIG. 11, both the second and third coils 42 and 43 in the third unit 70 are formed in an open annular shape in plan view. The second coil 42 is open toward the third coil 43 in the X-direction. The third coil 43 is open toward the second coil 42 in the X-direction. The second coil 42 is an example of a “coil of a third insulation element”, and the third coil 43 is an example of a “coil of a fourth insulation element”. The term “annular” as used in this description may refer to any structure that forms a loop, which is a continuous shape with no ends, as well as a generally loop-shaped structure with a gap, such as a C-shape. “Annular” shapes include, but are not limited to, a circular shape, an elliptic shape, and a polygonal shape with sharp or rounded corners.

The second coil 42 includes a first coil end portion 42A and a second coil end portion 42B, which are spaced apart from each other. In one example, the first and second coil end portions 42A and 42B are arranged at the same position in the X-direction and spaced apart from each other in the Y-direction.

The third coil 43 includes a third coil end portion 43A and a fourth coil end portion 43B, which are spaced apart from each other. In one example, the third and fourth end portions 43A and 43B are arranged at the same position in the X-direction and spaced apart from each other in the Y-direction. The third coil end portion 43A is placed at a position opposed to the first coil end portion 42A in the X-direction. The fourth coil end portion 43B is placed at a position opposed to the second coil end portion 42B in the X-direction.

The third unit 70 includes connection wiring lines 110, which connect the second coil 42 and the third coil 43. As shown in FIG. 12, the second coil 42, the third coil 43, and the connection wiring lines 110 are at the same position in the Z-direction.

As shown in FIG. 11, the connection wiring lines 110 include a first connection wiring line 111, which connects the first coil end portion 42A of the second coil 42 and the third coil end portion 43A of the third coil 43, and a second connection wiring line 112, which connects the second coil end portion 42B of the second coil 42 and the fourth coil end portion 43B of the third coil 43. Both the first connection wiring line 111 and the second connection wiring line 112 extend in the X-direction in plan view. The first connection wiring line 111 and the second connection wiring line 112 are spaced apart from each other in the Y-direction.

Since the second coil 42 is a single open loop, the number of turns of the second coil 42 is less than the number of turns of the first coil 41. Since the third coil 43 is a single open loop, the number of turns of the third coil 43 is less than the number of turns of the fourth coil 44.

### Advantages

The semiconductor device 10 of the second embodiment has the following advantages, as well as the same advantages as the first embodiment.

(2-1) The third unit 70 includes the connection wiring lines 110, which connect the second coil 42 and the third coil 43. The second coil 42, the third coil 43, and the connection wiring lines 110 are placed at the same position in the Z-direction.

According to this configuration, the number of insulating layers in the third element insulating layer 72 of the third unit 70 can be reduced as compared with a configuration in which the connection wiring lines 110 are provided in an insulating layer different from that of the second and third coils 42 and 43. This reduces the height and cost of the semiconductor device 10.

### Modifications of Second Embodiment

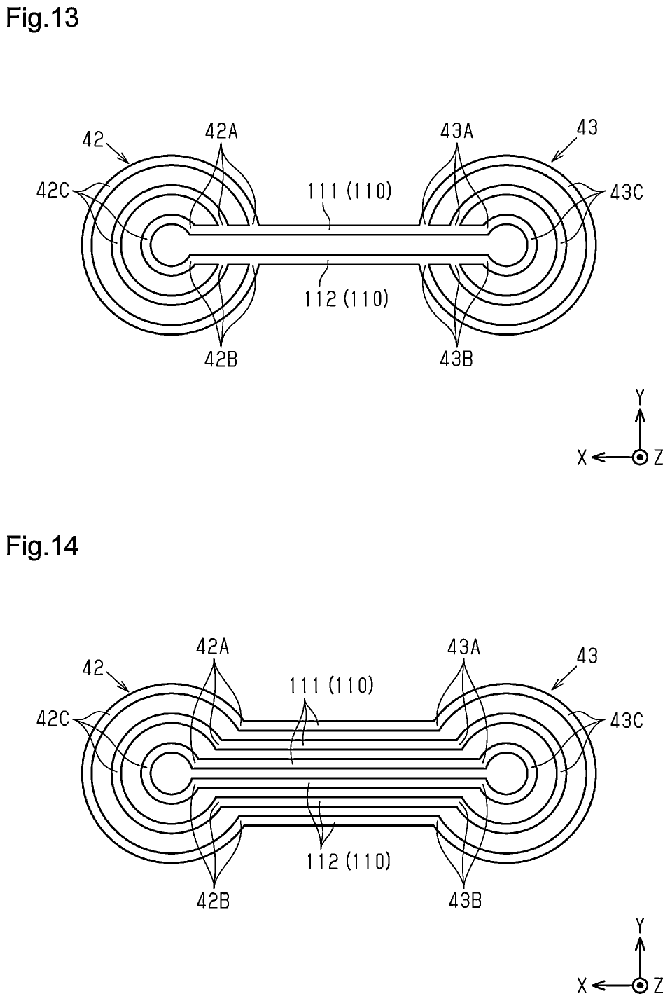

Referring to FIGS. 13 and 14, modifications of the configuration of the third and fourth coils 43 and 44 are described as modifications of the semiconductor device 10 of the second embodiment. FIGS. 13 and 14 both schematically show planar structures of the second coil 42, the third coil 43, and the connection wiring lines 110.

As shown in FIG. 13, the second coil 42 includes multiple first concentric coils 42C formed in a concentric pattern. Each first concentric coil 42C has an open annular shape. Each first concentric coil 42C includes a first coil end portion 42A and a second coil end portion 42B, which are spaced apart from each other. Each first concentric coil 42C is open toward the third coil 43 in the X-direction. The first coil end portions 42A are arranged at the same position in the Y-direction and spaced apart from one another in the X-direction. The second coil end portions 42B are spaced apart from the first coil end portions 42A in the Y-direction. The second coil end portions 42B are arranged at the same position in the Y-direction and spaced apart from one another in the X-direction.

The third coil 43 includes multiple second concentric coils 43C formed in a concentric pattern. Each second concentric coil 43C has an open annular shape. Each second concentric coil 43C includes a third coil end portion 43A and a fourth coil end portion 43B, which are spaced apart from each other. Each second concentric coil 43C is open toward the second coil 42 in the X-direction. The third coil end portions 43A are arranged at the same position in the Y-direction and spaced apart from one another in the X-direction. The fourth coil end portions 43B are spaced apart from the third coil end portions 43A in the Y-direction. The fourth coil end portions 43B are arranged at the same position in the Y-direction and spaced apart from one another r in the X-direction. The third coil end portions 43A are placed at the same position in the Y-direction as the first coil end portions 42A. The fourth coil end portions 43B are placed at the same position in the Y-direction as the second coil end portions 42B.

The single first connection wiring line 111 connects the first coil end portions 42A and the third coil end portions 43A. The first connection wiring line 111 extends in the X-direction. The single second connection wiring line 112 connects the second coil end portions 42B and the fourth coil end portions 43B. The second connection wiring line 112 extends in the X-direction. According to this configuration, the number of turns of the second coil 42 and the number of turns of the third coil 43 can be increased, and the advantages of the second embodiment are also achieved.

As shown in FIG. 14, the second coil 42 includes multiple first concentric coils 42C, in a similar manner as the second coil 42 shown in FIG. 13. The third coil 43 includes multiple second concentric coils 43C, in a similar manner as the third coil 43 shown in FIG. 13.

The connection wiring lines 110 include multiple first connection wiring lines 111 and multiple second connection wiring lines 112. The first connection wiring lines 111 individually connect the first coil end portions 42A and the third coil end portions 43A. The second connection wiring lines 112 individually connect the second coil end portions 42B and the fourth coil end portions 43B. The first connection wiring lines 111 and the second connection wiring lines 112 extend in the X-direction. According to this configuration, the number of turns of the second coil 42 and the number of turns of the third coil 43 can be increased, and the advantages of the second embodiment are also achieved. The number of the first concentric coils 42C and the number of the second concentric coils 43C are not limited to the examples shown in FIGS. 13 and 14, and may be freely modified.

### Third Embodiment

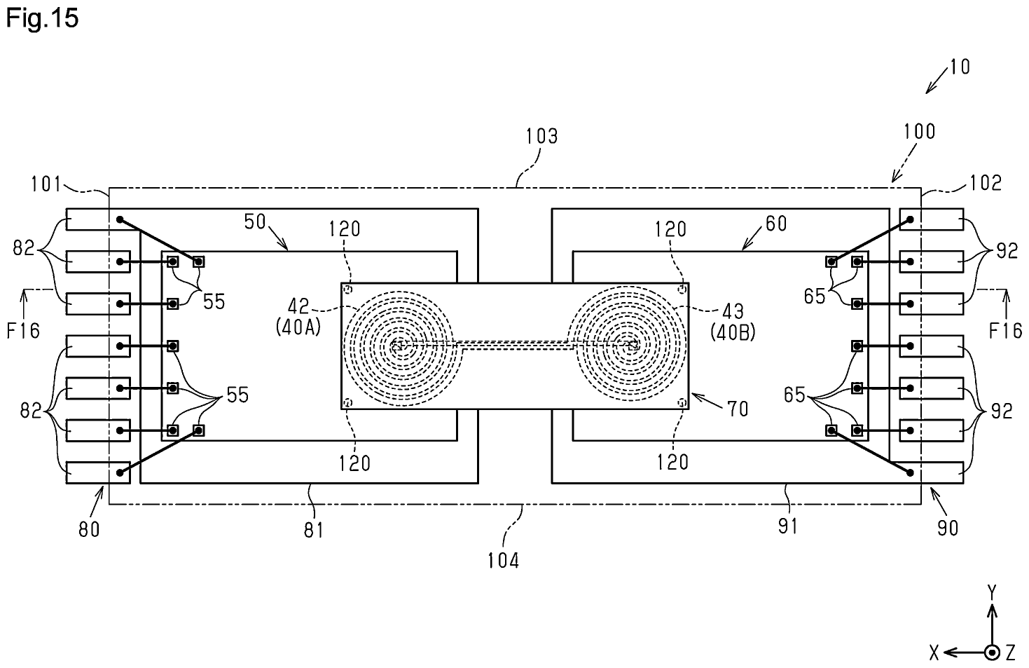

Referring to FIGS. 15 to 17, a semiconductor device 10 according to a third embodiment is now described. The semiconductor device 10 of the third embodiment differs from the semiconductor device 10 of the first embodiment mainly in positioning portions 120, which are added to position the third unit 70 relative to the first and second units 50 and 60. In the following description, the differences from the first embodiment are described in detail, and components common to the first embodiment are given the same reference numerals and descriptions thereof are omitted.

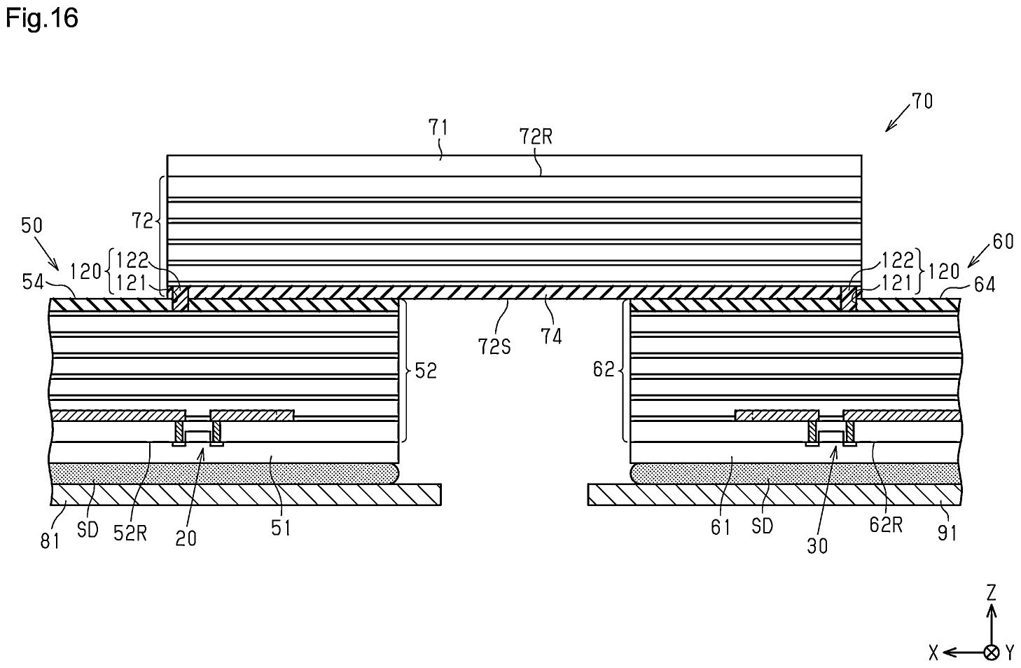

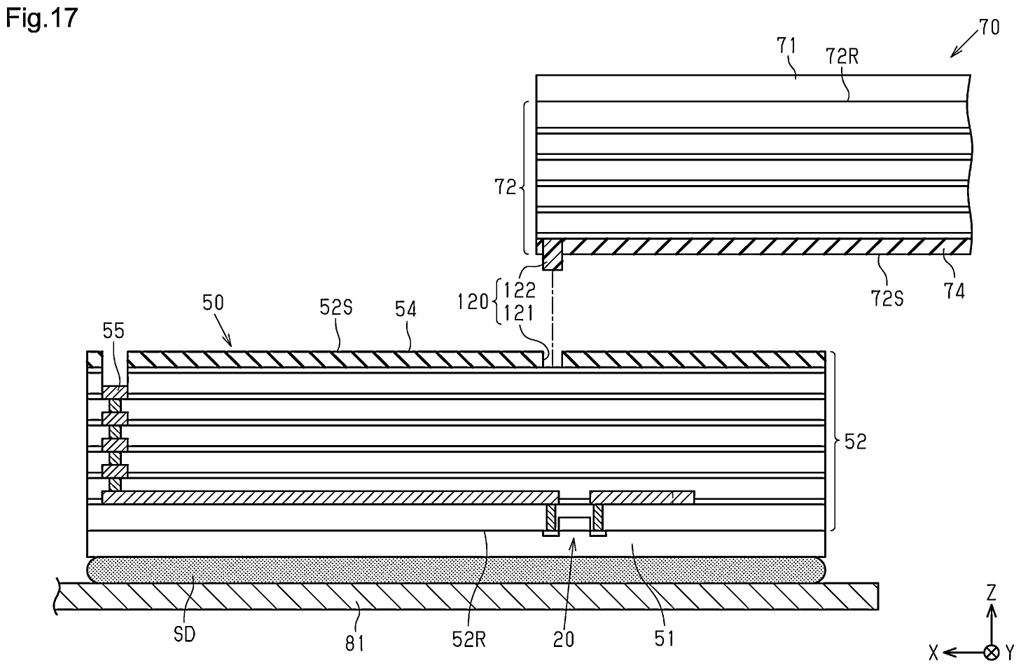

FIG. 15 schematically shows a planar structure of the semiconductor device 10 according to the third embodiment. FIG. 16 schematically shows a cross-sectional structure of the semiconductor device 10 taken along line F16-F16 in FIG. 15. FIG. 17 schematically shows a cross-sectional structure of the third unit 70 and the first unit 50 in a separated state.

As shown in FIG. 15, the positioning portions 120 are provided at the four corners of the third unit 70. That is, the positioning portions 120 are provided outward of the first to fourth coils 41 to 44 in plan view. As shown in FIGS. 16 and 17, the positioning portions 120 include recesses 121, which are provided in both the first unit 50 and the second unit 60, and bumps 122, which are provided on the third unit 70.

As shown in FIG. 16, the recesses 121 in the first unit 50 extend through the first passivation film 54 of the first unit 50 in the Z-direction. The recesses 121 in the first unit 50 are provided at positions corresponding to two of the four corners of the third unit 70 in the unit arrangement state.

The recesses 121 in the second unit 60 extend through the second passivation film 64 of the second unit 60 in the Z-direction. The recesses 121 in the second unit 60 are provided at positions corresponding to the two of the four corners of the third unit 70 other than the ones corresponding to the first unit 50 in the unit arrangement state.

As shown in FIG. 15, the bumps 122 of the third unit 70 are provided at the four corners of the third unit 70 in plan view. As shown in FIG. 17, each bump 122 is formed in a columnar shape, such as a cylindrical shape or a rectangular column shape. The bumps 122 are attached to the third unit 70 so as to extend through the third passivation film 74 in the Z-direction, for example. The bumps 122 protrude from the third element surface 72S of the third element insulating layer 72 in the Z-direction. The bumps 122 are inserted into the recesses 121 of the first unit 50 and the recesses 121 of the second unit 60 in a distributed manner.

The bumps 122 may be made of a metal material such as Cu or Al. In this case, the bumps 122 are in an electrically floating state. The material of the bumps 122 may be an insulating material such as a resin material or ceramic, instead of a metal material.

### Advantages

The semiconductor device 10 of the third embodiment has the following advantages, as well as the same advantages as the first embodiment.

(3-1) The first unit 50, the second unit 60, and the third unit 70 include the positioning portions 120, which position the third unit 70 relative to the first unit 50 and the second unit 60. According to this configuration, the positioning portions 120 allow the third unit 70 to be easily placed at a preset position relative to the first and second units 50 and 60.

(3-2) The positioning portions 120 includes recesses 121, which are provided in both the first unit 50 and the second unit 60, and bumps 122, which are provided on the third unit 70.

According to this configuration, the bumps 122 of the third unit 70 are fitted into the recesses 121 of both the first unit 50 and the second unit 60, facilitating the placement of the third unit 70 in a preset manner relative to the first and second units 50 and 60. Also, the bumps 122 are restricted from moving in directions perpendicular to the Z-direction within the recesses 121. Thus, in the step of forming the sealing plastic 100, for example, the resin material for the sealing plastic 100 is less likely to move the third unit 70 relative to the first and second units 50 and 60 in directions perpendicular to the Z-direction.

### Modifications of Third Embodiment

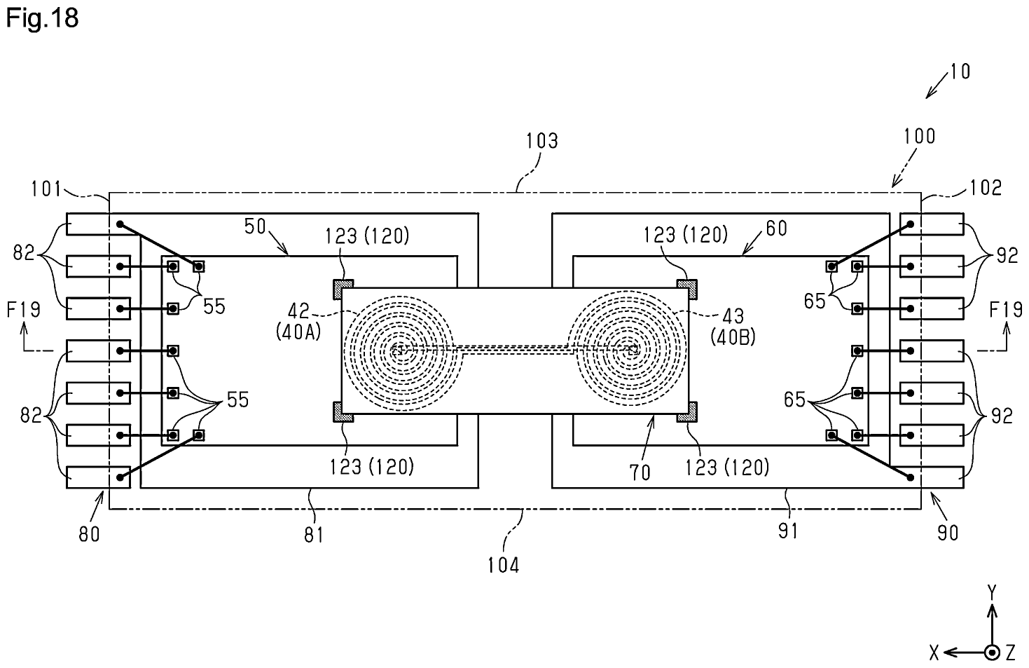

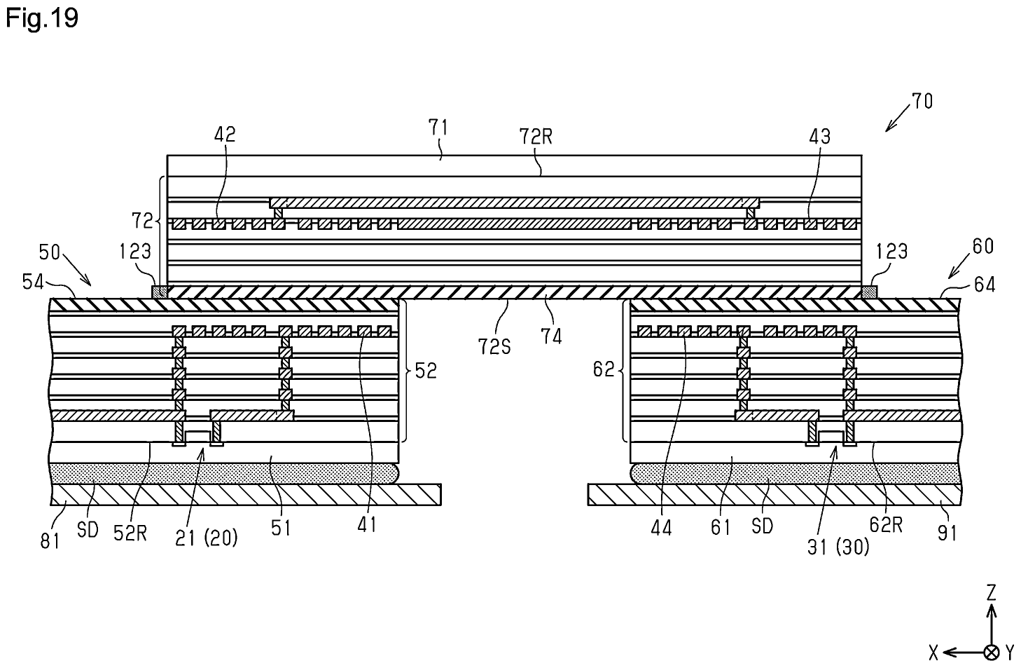

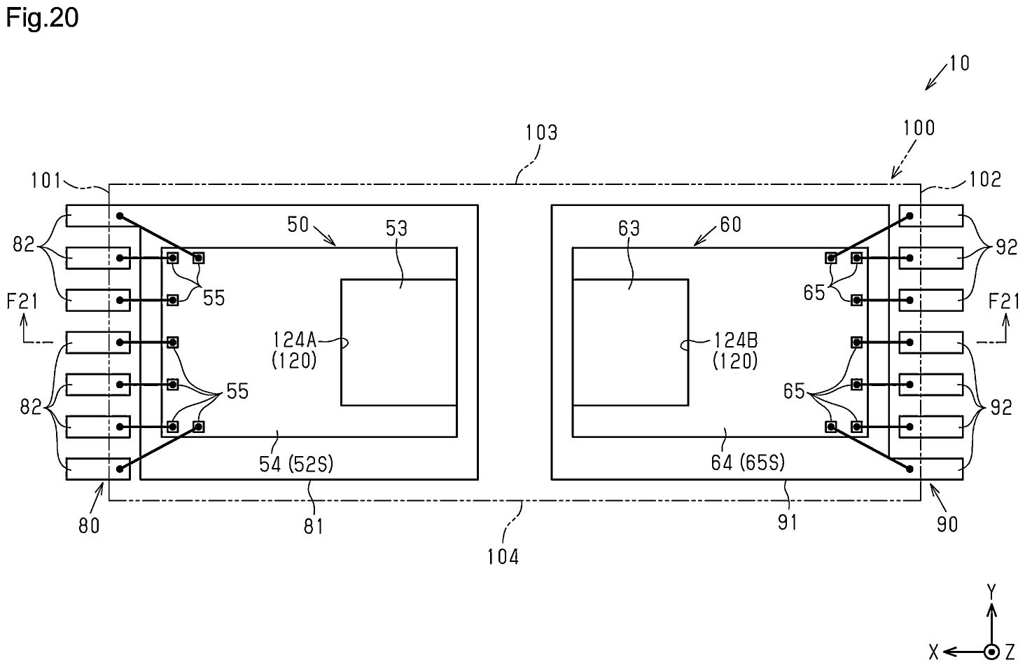

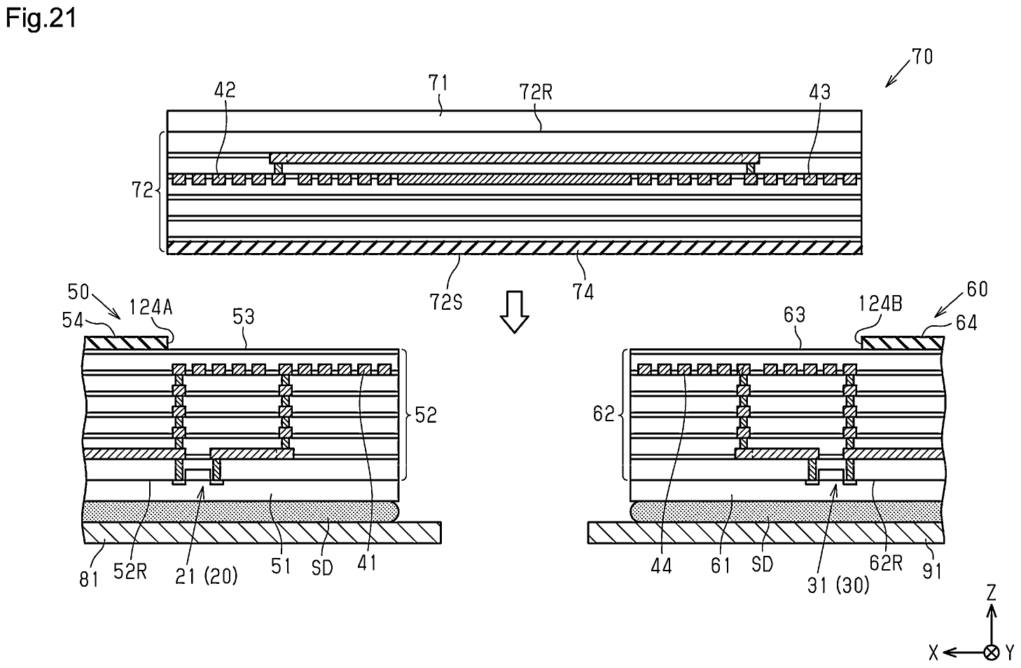

Referring to FIGS. 18 to 21, modifications of the semiconductor device 10 according to the third embodiment are now described. FIG. 18 schematically shows a planar structure of the semiconductor device 10 according to a first modification. FIG. 19 schematically shows a cross-sectional structure of the semiconductor device 10 taken along line F19-F19 in FIG. 18. FIG. 20 schematically shows a planar structure of the semiconductor device 10 of a second modification, in which the third unit 70 is omitted. FIG. 21 schematically shows a cross-sectional structure of the semiconductor device 10 taken along line F21-F21 in FIG. 20, in which the third unit 70 is separated from the first and second units 50 and 60.

As shown in FIGS. 18 and 19, in the semiconductor device 10 of the first modification, the positioning portions 120 include positioning marks 123, which are formed on both the first element surface 52S of the first element insulating layer 52 of the first unit 50 and the second element surface 62S of the second element insulating layer 62 of the second unit 60.

As shown in FIG. 18, four positioning marks 123 are provided to correspond to the four corners of the third unit 70. Each positioning mark 123 has an L-shape around the side surface of the third unit 70 in plan view. The positioning marks 123 are made of a metal material such as Cu or Al. The positioning marks 123 are formed on the first passivation film 54 of the first unit 50 and on the second passivation film 64 of the second unit 60 by sputtering, for example. As shown in FIG. 19, the positioning marks 123 are in contact with the side surface of the third unit 70 in the unit arrangement state.

According to this configuration, when the third unit 70 is placed on the first unit 50 and on the second unit 60, the third unit 70 is placed in accordance with the positioning marks 123 through image processing, for example. This allows the third unit 70 to be positioned with high precision relative to the first and second units 50 and 60. Additionally, since the positioning marks 123 are in contact with the side surface of the third unit 70 in the unit arrangement state, the resin material for the sealing plastic 100 is less likely to move the third unit 70 relative to the first and second units 50 and 60 in the step of forming the sealing plastic 100, for example.

The positioning marks 123 are provided on both the first unit 50 and the second unit 60, but the present disclosure is not limited to this. In one example, the two positioning marks 123 of the second unit 60 may be omitted. In one example, the two positioning marks 123 of the first unit 50 may be omitted. In one example, one of the two positioning marks 123 of the first unit 50 and one of the two positioning marks 123 of the second unit 60 may be omitted.

As shown in FIGS. 20 and 21, in the second modification of the semiconductor device 10, the positioning portions 120 are formed by cutting out both the first passivation film 54 of the first unit 50 and the second passivation film 64 of the second unit 60 in accordance with the third unit 70. More specifically, as shown in FIG. 20, the first passivation film 54 includes a first cutout section 124A as a positioning portion 120, and the second passivation film 64 includes a second cutout section 124B as a positioning portion.

The first and second cutout sections 124A and 124B are formed in a rectangular shape in accordance with the side surface of the third unit 70 in plan view. The first cutout section 124A is formed in a section closer to the second unit 60 than the center of the first unit 50 in the X-direction. The first cutout section 124A is open toward the second unit 60 at the end portion of the first unit 50 that is closer to the second unit 60 in the X-direction in plan view. The second cutout section 124B is formed in a section closer to the first unit 50 than the center of the second unit 60 in the X-direction. The second cutout section 124B is open toward the first unit 50 at the end portion of the second unit 60 that is closer to the first unit 50 in the X-direction in plan view. The first cutout section 124A extends through the first passivation film 54 in the Z-direction, thereby exposing the first protective film 53 in plan view. The second cutout section 124B extends through the second passivation film 64 in the Z-direction, thereby exposing the second protective film 63 in plan view.

As shown in FIG. 21, the third unit 70 is placed within the first and second cutout sections 124A and 124B. As such, the third passivation film 74 of the third element insulating layer 72 in the third unit 70 is in contact with the first protective film 53 and the second protective film 63 in the unit arrangement state.

According to this configuration, when the third unit 70 is placed on the first unit 50 and on the second unit 60, the third unit 70 is fitted into the first and second cutout sections 124A and 124B. This allows the third unit 70 to be positioned with high precision relative to the first and second units 50 and 60. Additionally, since both the first and second passivation films 54 and 64 are in contact with the side surface of the third unit 70 in the unit arrangement state, the resin material for the sealing plastic 100 is less likely to move the third unit 70 relative to the first and second units 50 and 60 in the step of forming the sealing plastic 100, for example.

### Modifications

The above-described embodiments may be modified as follows. The modified examples described below may be combined with one another as long as there is no technical inconsistency.

The second and third embodiments may be combined.

In the third embodiment, the number of positioning portions 120 may be freely modified, provided at least one positioning portion 120 is formed.

In the third embodiment, the bumps 122 are provided on the third unit 70, and the recesses 121 are provided in both the first unit 50 and the second unit 60, but there is no limitation to this. For example, the third unit 70 may include recesses 121, and the first unit 50 and the second unit 60 may include bumps 122.

In each embodiment, the positions of the first coil 41 and the fourth coil 44 in the Z-direction may be freely modified.

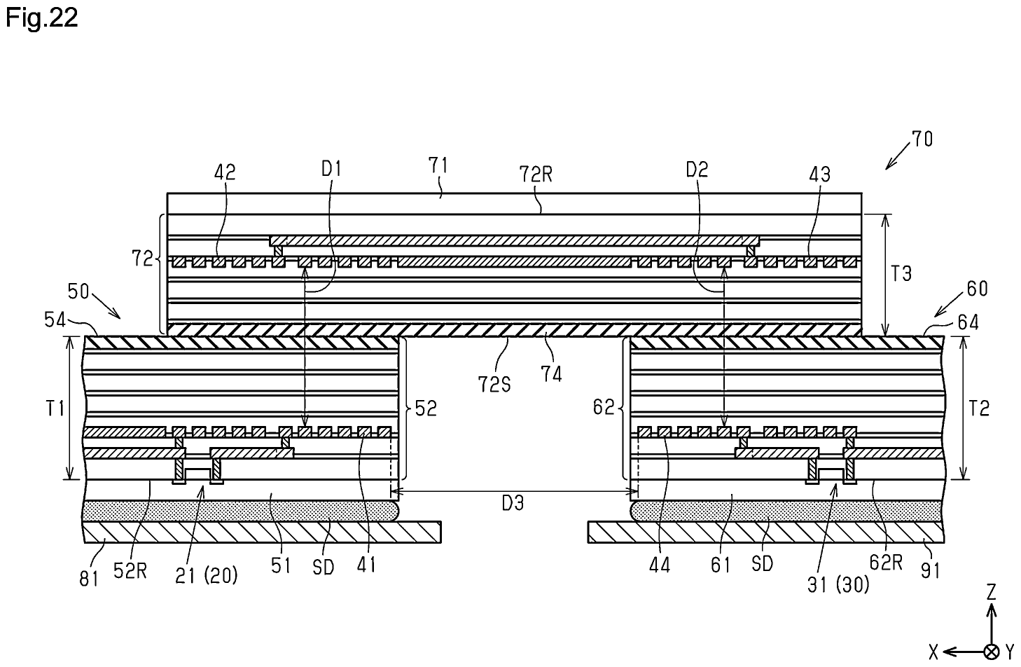

In one example, as shown in FIG. 22, the first coil 41 may be placed closer to the first semiconductor substrate 51 than the center of the first element insulating layer 52 is in the Z-direction. In other words, the first coil 41 may be placed closer to the first element back surface 52R than the center of the first element insulating layer 52 is in the Z-direction. This allows the distance D1 between the first coil 41 and the second coil 42 in the Z-direction to be greater than or equal to the thickness T1 of the first element insulating layer 52. As a result, the withstand voltage of the semiconductor device 10 can be increased as compared with a configuration in which the distance D1 is less than the thickness T1 of the first element insulating layer 52. Furthermore, the distance D1 may be greater than or equal to the thickness T3 of the third element insulating layer 72 of the third unit 70. As a result, the withstand voltage of the semiconductor device 10 can be increased as compared with a configuration in which the distance D1 is less than the thickness T3 of the third element insulating layer 72.

In one example, the fourth coil 44 may be placed closer to the second semiconductor substrate 61 than the center of the second element insulating layer 62 is in the Z-direction. In other words, the fourth coil 44 may be placed closer to the second element back surface 62R than the center of the second element insulating layer 62 is in the Z-direction. This allows the distance D2 between the third coil 43 and the fourth coil 44 in the Z-direction to be greater than or equal to the thickness T2 of the second element insulating layer 62. As a result, the withstand voltage of the semiconductor device 10 can be increased as compared with a configuration in which the distance D2 is less than the thickness T2 of the second element insulating layer 62. Furthermore, the distance D2 may be greater than or equal to the thickness T3 of the third element insulating layer 72 of the third unit 70. As a result, the withstand voltage of the semiconductor device 10 can be increased as compared with a configuration in which the distance D2 is less than the thickness T3 of the third element insulating layer 72. In the modification shown in FIG. 22, any one of the configuration of the second coil 42 and the third coil 43 of the third embodiment, the configuration of the second coil 42 and the third coil 43 shown in FIG. 13, and the configuration of the second coil 42 and the third coil 43 shown in FIG. 14 may be applied.

In each embodiment, the positions of the first coil 41 and the fourth coil 44 in directions perpendicular to the Z-direction may be freely modified. In one example, the first coil 41 may be placed at the center of the first element insulating layer 52 in the X-direction. In addition, in one example, the fourth coil 44 may be placed at the center of the second element insulating layer 62 in the X-direction.

In each embodiment, the positional relationship between the first and fourth coils 41 and 44 in the Z-direction may be freely modified. In one example, the first coil 41 may be placed closer to the third unit 70 than the fourth coil 44 is in the Z-direction. The first coil 41 may be placed at a position farther from the third unit 70 than the fourth coil 44 in the Z-direction. Furthermore, the fourth coil 44 may be placed closer to the third unit 70 than the first coil 41 is in the Z-direction. The fourth coil 44 may be placed at a position farther from the third unit 70 than the first coil 41 in the Z-direction.

In each embodiment, the positional relationship between the second and third coils 42 and 43 in the Z-direction may be freely modified. In one example, the second coil 42 may be placed closer to the third element back surface 72R of the third element insulating layer 72 than the third coil 43 is in the Z-direction. The second coil 42 may be placed closer to the third element surface 72S of the third element insulating layer 72 than the third coil 43 is in the Z-direction. In one example, the third coil 43 may be placed closer to the third element back surface 72R than the second coil 42 is in the Z-direction. The third coil 43 may be placed closer to the third element surface 72S than the second coil 42 is in the Z-direction.

In each embodiment, the relationship between the distance D1 between the first and second coils 41 and 42 in the Z-direction and the distance D2 between the third and fourth coils 43 and 44 in the Z-direction may be freely modified. In one example, the distance D1 may be greater than the distance D2, or the distance D2 may be greater than the distance D1.

In each embodiment, the positional relationship between the transmitting circuit 21 of the first circuit 20 and the first coil 41 provided in the first unit 50 may be freely modified. In one example, the transmitting circuit 21 may be placed outward of the first coil 41 in plan view.

In each embodiment, the positional relationship between the receiving circuit 31 of the second circuit 30 and the fourth coil 44 provided in the second unit 60 may be freely modified. In one example, the receiving circuit 31 may be placed outward of the fourth coil 44 in plan view.

In each embodiment, the first circuit 20, provided in the first unit 50, may include a receiving circuit instead of the transmitting circuit 21. In this case, the second circuit 30, provided in the second unit 60, may include a transmitting circuit instead of the receiving circuit 31.

In each embodiment, the first circuit 20, provided in the first unit 50, may include both a transmitting circuit 21 and a receiving circuit. The second circuit 30, provided in the second unit 60, may include both a transmitting circuit and a receiving circuit 31.

In each embodiment, the configuration of the first element insulating layer 52 of the first unit 50 may be freely modified. In one example, the first insulating films 52P may be omitted from the first element insulating layer 52. In other words, the first element insulating layer 52 may have a laminate structure of multiple second insulating films 52Q.

In each embodiment, the configuration of the second element insulating layer 62 of the second unit 60 may be freely modified. In one example, the first insulating films 62P may be omitted from the second element insulating layer 62. In other words, the second element insulating layer 62 may have a laminate structure of multiple second insulating films 62Q.

In each embodiment, the configuration of the third element insulating layer 72 of the third unit 70 may be freely modified. In one example, the first insulating films 72P may be omitted from the third element insulating layer 72. In other words, the third element insulating layer 72 may have a laminate structure of multiple second insulating films 72Q.

In each embodiment, the third unit 70 may be bonded to the first and second units 50 and 60 by an adhesive. In this case, the adhesive is in contact with the third element surface 72S of the third element insulating layer 72 and the first element surface 52S of the first element insulating layer 52. The adhesive is also in contact with the third element surface 72S and the second element surface 62S of the second element insulating layer 62.

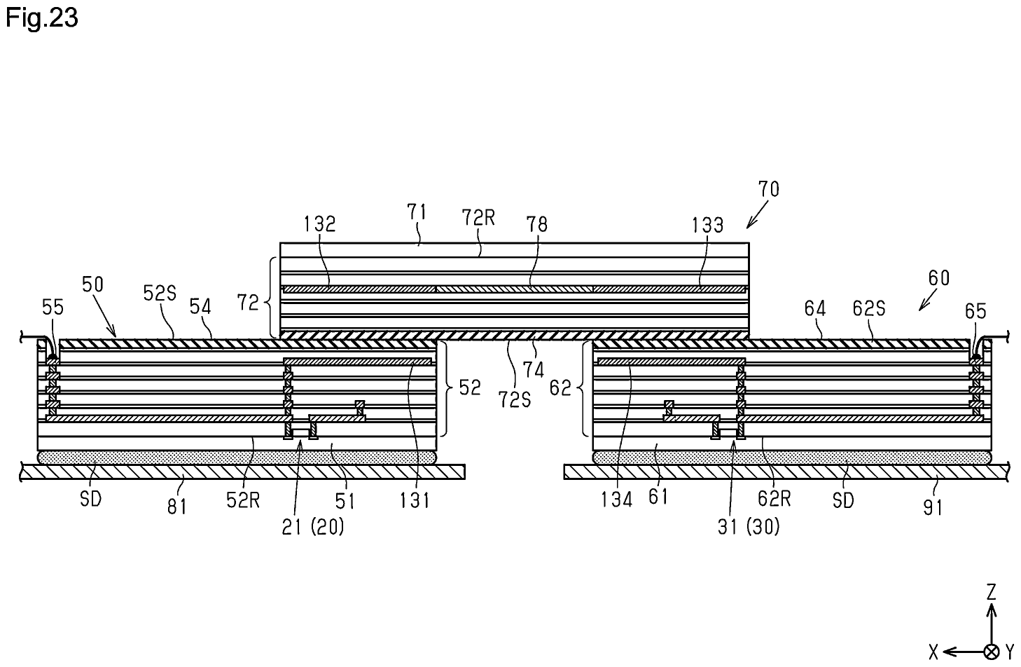

In each embodiment, the first to fourth insulation elements are not limited to the first to fourth coils 41 to 44. In one example, as shown in FIG. 23, each of the first to fourth insulation elements may be an electrode plate. That is, the first unit 50 includes a first electrode plate 131 instead of the first coil 41 as the first insulation element. The second unit 60 includes a fourth electrode plate 134 instead of the fourth coil 44 as the second insulation element. The third unit 70 includes a second electrode plate 132 and a third electrode plate 133 instead of the second coil 42 and the third coil 43 as the third and fourth insulation elements. In the third unit 70, the connection wiring layer 78 is placed at the same position as the second electrode plate 132 and the third electrode plate 133 in the Z-direction. Thus, the first connection wiring line 75 and the second connection wiring line 76 are omitted from the third unit 70.

In the unit arrangement state, the first electrode plate 131 and the second electrode plate 132 are opposed to each other. The first and second electrode plates 131 and 132 form a first capacitor. In the unit arrangement state, the third electrode plate 133 and the fourth electrode plate 134 are opposed to each other. The third and fourth electrode plates 133 and 134 form a second capacitor.

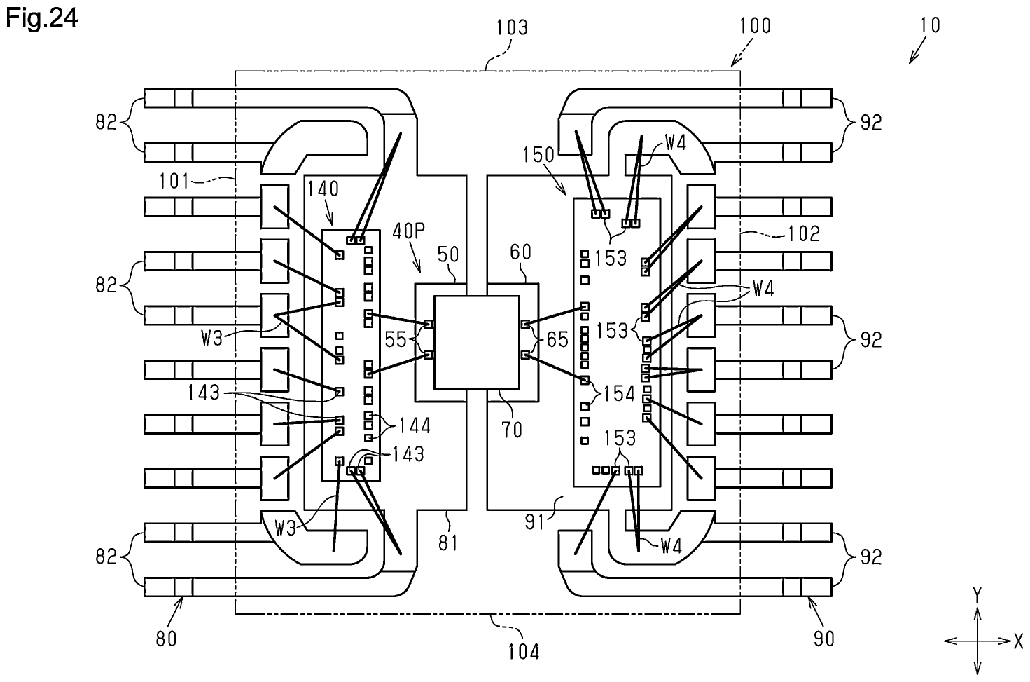

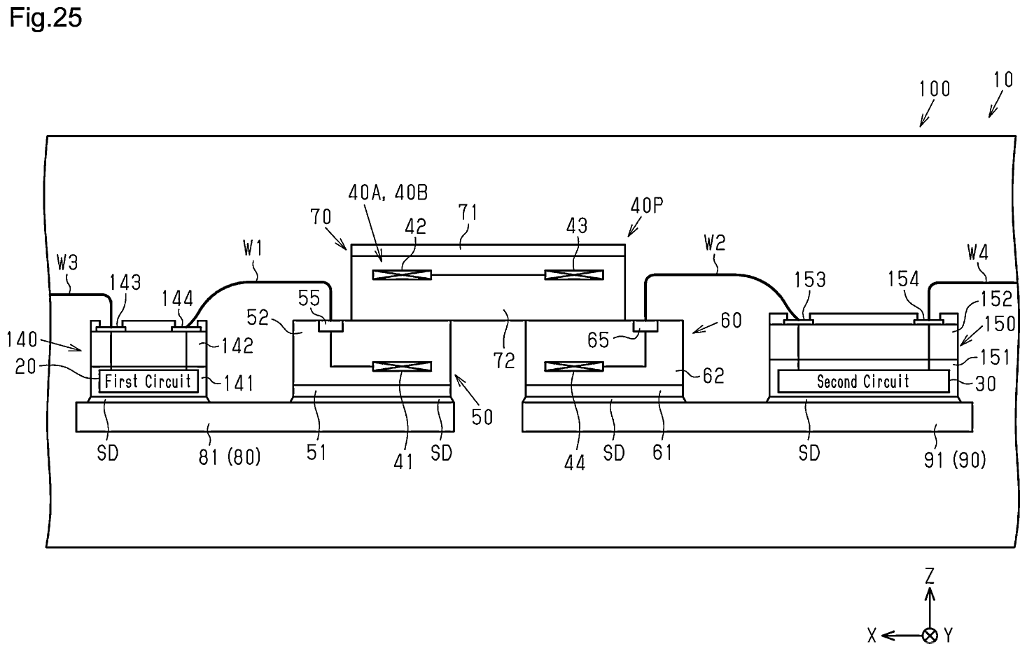

In each embodiment, the first unit 50 does not need to include the first circuit 20, and the second unit 60 does not need to include the second circuit 30. In one example, as shown in FIGS. 24 and 25, the semiconductor device 10 includes a first circuit chip 140, which is a semiconductor chip dedicated to the first circuit 20, and a second circuit chip 150, which is a semiconductor chip dedicated to the second circuit 30.

The first circuit chip 140 is placed on the first die pad 81. The second circuit chip 150 is placed on the second die pad 91. The insulation chip 40P is placed between the first and second circuit chips 140 and 150 in the X-direction.

As shown in FIG. 25, the first circuit chip 140 includes a semiconductor substrate 141, an element insulating layer 142 formed on the semiconductor substrate 141, and multiple first pads 143 and multiple second pads 144 formed in the element insulating layer 142. The first circuit 20 is formed on the semiconductor substrate 141, for example. The first circuit 20 is electrically connected to a predetermined first pad 143 and a predetermined second pad 144 via a wiring layer formed in the element insulating layer 142.

As shown in FIG. 24, the first pads 143 are individually and electrically connected to the first leads 82 by wires W3. The second pads 144 are individually and electrically connected to the first pads 55 of the first unit 50 by wires W1. As a result, the first coil 41 (see FIG. 3) is electrically connected to the first circuit 20.

As shown in FIG. 25, the second circuit chip 150 includes a semiconductor substrate 151, an element insulating layer 152, which is formed on the semiconductor substrate 151, and first pads 153 and second pads 154, which are formed on the element insulating layer 152. The second circuit 30 is formed on a semiconductor substrate 151, for example. The second circuit 30 is electrically connected to the first pads 153 and the second pads 154 via a wiring layer formed in the element insulating layer 152.

As shown in FIG. 24, the first pads 153 are individually and electrically connected to the second leads 92 by wires W4. The second pads 154 are individually and electrically connected to the second pads 65 of the second unit 60 by wires W2. As a result, the fourth coil 44 (see FIG. 3) is electrically connected to the second circuit 30.

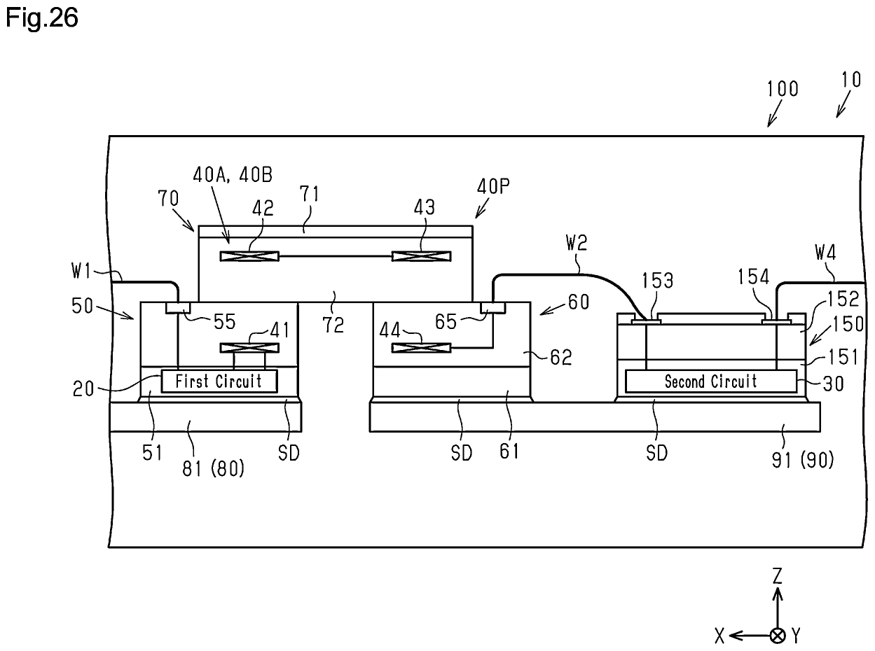

In each embodiment, the second unit 60 does not need to include the second circuit 30. In one example, as shown in FIG. 26, the semiconductor device 10 includes an insulation chip 40P and a second circuit chip 150, which is a semiconductor chip dedicated to the second circuit 30. The second circuit chip 150 has the same configuration as the second circuit chip 150 in FIGS. 24 and 25.

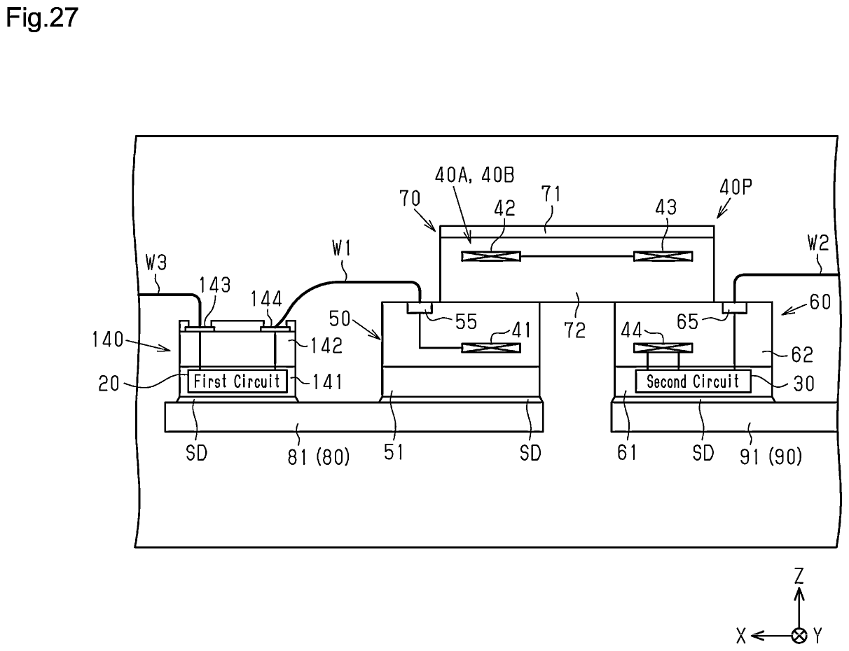

In each embodiment, the first unit 50 does not need to include the first circuit 20. In one example, as shown in FIG. 27, the semiconductor device 10 includes an insulation chip 40P and a first circuit chip 140, which is a semiconductor chip dedicated to the first circuit 20. The first circuit chip 140 has the same configuration as the first circuit chip 140 in FIGS. 24 and 25.

In each of the embodiments and modifications, the semiconductor device 10 is embodied as a signal transmission device, but the present disclosure is not limited to this. For example, the semiconductor device 10 may be embodied as a power transmission device that transmits power. In this case, the semiconductor device 10 is electrically connected to a DC power supply. The first circuit 20 of the semiconductor device 10 may include an inverter circuit and a control circuit that controls the inverter circuit, for example. The second circuit 30 may include a rectifier circuit and a capacitor, for example. In the semiconductor device 10, the inverter circuit converts the power of the DC power supply into AC power and outputs it to the transformers 40A and 40B (capacitors 120A and 120B). The AC power is input to a rectifier circuit via transformers 40A and 40B (capacitors 120A and 120B) and converted into DC power. Then, DC power is supplied to a load electrically connected to the semiconductor device 10.

One or more of the various examples described in this specification may be combined within a range where there is no technical inconsistency.

In the present disclosure, the term “on” includes the meaning of “above” in addition to the meaning of “on” unless otherwise clearly indicated in the context. Therefore, for example, the phrase “first component disposed on second component” is intended to mean that the first component may be disposed on the second component in contact with the second component in one embodiment and that the first component may be disposed above the second component without contacting the second component in another embodiment. In other words, the term “on” does not exclude a structure in which another component is formed between the first component and the second component.

The Z-direction referred to in the present disclosure does not necessarily have to be the vertical direction and does not necessarily have to exactly coincide with the vertical direction. In the structures according to the present disclosure, “upward” and “downward” in the z-direction as referred to in the present description are not limited to “upward” and “downward” in the vertical direction. For example, the X-direction may conform to the vertical direction. The Y-direction may conform to the vertical direction.

### CLAUSES

The technical ideas obtainable from the present disclosure are described below. The reference characters used to denote elements of the embodiments are shown in parenthesis for the corresponding elements of the clauses described below. The reference signs used as examples to facilitate understanding, and the elements in each clause are not limited to those elements given with the reference signs.

### Clause 1

An insulation chip (40P), including:
a first unit (50) and a second unit (60) arranged to be spaced apart from each other in a first direction (X-direction); and
a third unit (70) placed on the first unit (50) and on the second unit (60) so as to extend over a space between the first unit (50) and the second unit (60) in the first direction (X-direction), in which
the first unit (50) includes:
   a first semiconductor substrate (51);
   a first element insulating layer (52) including a first element surface (52S) facing the third unit (70) and a first element back surface (52R) opposite to the first element surface (52S), the first element back surface (52R) being in contact with the first semiconductor substrate (51); and
   a first insulation element (41) embedded in the first element insulating layer (52) at a position spaced apart from the first element surface (52S) in a thickness direction (Z-direction) of the first element insulating layer (52),
the second unit (60) includes:
   a second semiconductor substrate (61);
   a second element insulating layer (62) including a second element surface (62S) facing the third unit (70) and a second element back surface (62R) opposite to the second element surface (62S), the second element back surface (62R) being in contact with the second semiconductor substrate (61); and
   a second insulation element (44) embedded in the second element insulating layer (62) at a position spaced apart from the second element surface (62S) in a thickness direction (Z-direction) of the second element insulating layer (62),
the third unit (70) includes:
   a third semiconductor substrate (71);
   a third element insulating layer (72) including a third element surface (72S) and a third element back surface (72R) opposite to the third element surface (72S), the third element back surface (72R) being in contact with the third semiconductor substrate (71); and
   a third insulation element (42) and a fourth insulation element (43) that are embedded in the third element insulating layer (72) at positions spaced apart from the third element surface (72S) in a thickness direction (Z-direction) of the third element insulating layer (72), the third insulation element (42) and the fourth insulation element (43) being spaced apart from each other in the first direction (X-direction) and electrically connected to each other, and
in a unit arrangement state in which the third element insulating layer (72) of the third unit (70) is arranged on both the first element insulating layer (52) of the first unit (50) and the second element insulating layer (62) of the second unit (60), the first insulation element (41) and the third insulation element (42) are placed to face each other in the thickness direction (Z-direction) of the first element insulating layer (52), and the second insulation element (44) and the fourth insulation element (43) are placed to face each other in the thickness direction (Z-direction) of the second element insulating layer (62).

### Clause 2

The insulation chip according to clause 1, in which at least one of the first unit (50), the second unit (60), or the third unit (70) includes a positioning portion (120) that positions the third unit (70) relative to the first unit (50) and the second unit (60).

### Clause 3

The insulation chip according to clause 2, in which the positioning portion (120) includes one of a bump (122) and a recess (121) provided in at least one of the first unit (50) or the second unit (60), and the other of the bump (122) and the recess (121) provided in the third unit (70).

### Clause 4

The insulation chip according to clause 2, in which the positioning portion (120) includes a positioning mark (123) formed on at least one of the first element surface (52S) of the first unit (50) or the second element surface (62S) of the second unit (60).

### Clause 5

The insulation chip according to clause 2, in which
the first element insulating layer (52) includes a first passivation film (54) that forms the first element surface (52S),
the second element insulating layer (62) includes a second passivation film (64) that forms the second element surface (62S), and
the positioning portion (120) is formed by cutting out both the first passivation film (54) and the second passivation film (64) in accordance with the third unit (70).

### Clause 6

The insulation chip according to any one of clauses 1 to 5, in which
the third unit (70) includes a connection wiring line (110) connecting the third insulation element (42) and the fourth insulation element (43), and
the third insulation element (42), the fourth insulation element (43), and the connection wiring line (110) are placed at a same position in the thickness direction (Z-direction) of the third element insulating layer (72).

### Clause 7

The insulation chip according to clause 6, in which
the third insulation element (42) includes a coil (42) that has an open annular shape, the coil (42) including a first coil end portion (42A) and a second coil end portion (42B) that are spaced apart from each other,
the fourth insulation element (43) includes a coil (43) that has an open annular shape, the coil (43) including a third coil end portion (43A) and a fourth coil end portion (43B) that are spaced apart from each other, and
the connection wiring line (110) includes:
   a first connection wiring line (111) connecting the first coil end portion (42A) and the third coil end portion (43A); and
   a second connection wiring line (112) connecting the second coil end portion (42B) and the fourth coil end portion (43B).

### Clause 8

The insulation chip according to clause 6, in which
the third insulation element (42) includes multiple first concentric coils (42C) each having an open annular shape, the first concentric coils (42C) being in a concentric pattern,
the fourth insulation element (43) includes multiple second concentric coils (43C) each having an open annular shape, the second concentric coils (43C) being in a concentric pattern,
each of the first concentric coils (42C) includes a first coil end portion (42A) and a second coil end portion (42B) spaced apart from each other,
each of the second concentric coils (43C) includes a third coil end portion (43A) and a fourth coil end portion (43B) spaced apart from each other, and
the connection wiring line (110) includes:
   a single first connection wiring line (111) connecting the first coil end portions (42A) and the third coil end portions (43A); and
   a single second connection wiring line (112) connecting the second coil end portions (42B) and the fourth coil end portions (43B).

### Clause 9

The insulation chip according to clause 6, in which
the third insulation element (42) includes multiple first concentric coils (42C) each having an open annular shape, the first concentric coils (42C) being in a concentric pattern,
the fourth insulation element (43) includes multiple second concentric coils (43C) each having an open annular shape, the second concentric coils (43C) being in a concentric pattern,
each of the first concentric coils (42C) includes a first coil end portion (42A) and a second coil end portion (42B) spaced apart from each other,
each of the second concentric coils (43C) includes a third coil end portion (43A) and a fourth coil end portion (43B) spaced apart from each other, and
the connection wiring line (110) includes:
   multiple first connection wiring lines (111) individually connecting the first coil end portions (42A) and the third coil end portions (43A); and
   multiple second connection wiring lines (112) individually connecting the second coil end portions (42B) and the fourth coil end portions (43B).

### Clause 10

The insulation chip according to any one of clauses 1 to 9, in which
the first unit (50) includes a first pad (55) electrically connected to the first insulation element (41), and
the first pad (55) is located on an opposite side of the second unit (60) with respect to the third unit (70) in the first direction (X-direction), and is exposed from the first element insulating layer (52) in the thickness direction (Z-direction) of the first element insulating layer (52).

### Clause 11

The insulation chip according to clause 10, in which a distance between the first pad (55) and the third insulation element (42) is greater than a distance (D1) between the first insulation element (41) and the third insulation element (42), the distance (D1) between the first insulation element (41) and the third insulation element (42) being the distance in the thickness direction (Z-direction) of the first element insulating layer (52).

### Clause 12

The insulation chip according to any one of clauses 1 to 11, in which
the second unit (60) includes a second pad (65) electrically connected to the second insulation element (44), and
the second pad (65) is located on an opposite side of the first unit (50) with respect to the third unit (70) in the first direction (X-direction), and is exposed from the second element insulating layer (62) in the thickness direction (Z-direction) of the second element insulating layer (62).

### Clause 13

The insulation chip according to clause 12, in which a distance between the second pad (65) and the fourth insulation element (43) is greater than a distance (D2) between the second insulation element (44) and the fourth insulation element (43), the distance (D2) between the second insulation element (44) and the fourth insulation element (43) being the distance in the thickness direction (Z-direction) of the second element insulating layer (62).

### Clause 14

The insulation chip according to any one of clauses 1 to 13, in which
the first unit (50) includes a first circuit (20), and
the second unit (60) includes a second circuit (30).

### Clause 15

The insulation chip according to clause 14, in which
the first circuit (20) includes a transmitting circuit (21) or a receiving circuit electrically connected to the first insulation element (41), and
the second circuit (30) includes a transmitting circuit or a receiving circuit (31) electrically connected to the second insulation element (44).

### Clause 16

The insulation chip according to clause 15, in which
the transmitting circuit (21) or the receiving circuit of the first circuit (20) is placed at a position overlapping the first insulation element (41) as viewed from the thickness direction (Z-direction) of the first element insulating layer (52), and
the transmitting circuit or the receiving circuit (31) of the second circuit (30) is placed at a position overlapping the second insulation element (44) as viewed from the thickness direction (Z-direction) of the second element insulating layer (62).

### Clause 17

The insulation chip according to any one of clauses 1 to 16, in which each of the first insulation element, the second insulation element, the third insulation element, and the fourth insulation element is a coil (41 to 44).

### Clause 18

The insulation chip according to any one of clauses 1 to 16, in which each of the first insulation element, the second insulation element, the third insulation element, and the fourth insulation element is an electrode plate (131 to 134).

### Clause 19

A semiconductor device (10) including the insulation chip (40P) according to any one of clauses 1 to 18, the semiconductor device including:
a first die pad (81) supporting the first unit (50);
a second die pad (91) supporting the second unit (60) and spaced apart from the first die pad (81) in the first direction (X-direction); and
sealing plastic (100) that seals the first die pad (81), the second die pad (91), the first unit (50), the second unit (60), and the third unit (70).

### Clause 20

The insulation chip according to any one of clauses 1 to 18, in which a distance (D1) between the first insulation element (41) and the third insulation element (42) in the thickness direction (Z-direction) of the first element insulating layer (52) is greater than or equal to a thickness (T1) of the first element insulating layer (52).

### Clause 21

The insulation chip according to any one of clauses 1 to 18, in which a distance (D2) between the second insulation element (44) and the fourth insulation element (43) in the thickness direction (Z-direction) of the second element insulating layer (62) is greater than or equal to a thickness (T2) of the second element insulating layer (62).

### Clause 22

The insulation chip according to any one of clauses 1 to 18, in which a distance (D1) between the first insulation element (41) and the third insulation element (42) in the thickness direction (Z-direction) of the first element insulating layer (52) is greater than or equal to a thickness (T3) of the third element insulating layer (72).

### Clause 23

The insulation chip according to any one of clauses 1 to 18, in which a distance (D2) between the second insulation element (44) and the fourth insulation element (43) in the thickness direction (Z-direction) of the second element insulating layer (62) is greater than or equal to a thickness (T3) of the third element insulating layer (72).

### Clause 24

The insulation chip according to clause 20, in which the first insulation element (41) is closer to the first element back surface (52R) than a center of the first element insulating layer (52) is in the thickness direction (Z-direction) of the first element insulating layer (52).

### Clause 25

The insulation chip according to clause 21, in which the second insulation element (44) is closer to the second element back surface (62R) than a center of the second element insulating layer (62) is in the thickness direction (Z-direction) of the second element insulating layer (62).

### Clause 26

The insulation chip according to clause 22 or 23, in which both the third insulation element (42) and the fourth insulation element (43) are closer to the third element back surface (72R) than a center of the third element insulating layer (72) is in the thickness direction (Z-direction) of the third element insulating layer (72).

### Clause 27

The insulation chip according to any one of clauses 1 to 18, in which a distance (D1) between the first insulation element (41) and the third insulation element (42) is equal to a distance (D2) between the second insulation element (44) and the fourth insulation element (43).

The above description is merely exemplary. One skilled in the art may recognize further possible combinations and replacements of the elements and methods (manufacturing processes) in addition to those listed for purposes of describing the techniques of the present disclosure. The present disclosure is intended to include any substitute, modification, changes included in the scope of the disclosure including the claims.

Various changes in form and details may be made to the examples above without departing from the spirit and scope of the claims and their equivalents. The examples are for the sake of description only, and not for purposes of limitation. Descriptions of features in each example are to be considered as being applicable to similar features or aspects in other examples. Suitable results may be achieved if sequences are performed in a different order, and/or if components in a described system, architecture, device, or circuit are combined differently, and/or replaced or supplemented by other components or their equivalents. The scope of the disclosure is not defined by the detailed description, but by the claims and their equivalents. All variations within the scope of the claims and their equivalents are included in the disclosure.

1. An insulation chip, comprising:
a first unit and a second unit arranged to be spaced apart from each other in a first direction; and
a third unit placed on the first unit and on the second unit so as to extend over a space between the first unit and the second unit in the first direction, wherein
the first unit includes:
a first semiconductor substrate;
a first element insulating layer including a first element surface facing the third unit and a first element back surface opposite to the first element surface, the first element back surface being in contact with the first semiconductor substrate; and
a first insulation element embedded in the first element insulating layer at a position spaced apart from the first element surface in a thickness direction of the first element insulating layer,
the second unit includes:
a second semiconductor substrate;
a second element insulating layer including a second element surface facing the third unit and a second element back surface opposite to the second element surface, the second element back surface being in contact with the second semiconductor substrate; and
a second insulation element embedded in the second element insulating layer at a position spaced apart from the second element surface in a thickness direction of the second element insulating layer,
the third unit includes:
a third semiconductor substrate;
a third element insulating layer including a third element surface and a third element back surface opposite to the third element surface, the third element back surface being in contact with the third semiconductor substrate; and
a third insulation element and a fourth insulation element that are embedded in the third element insulating layer at positions spaced apart from the third element surface in a thickness direction of the third element insulating layer, the third insulation element and the fourth insulation element being spaced apart from each other in the first direction and electrically connected to each other, and
in a unit arrangement state in which the third element insulating layer of the third unit is arranged on both the first element insulating layer of the first unit and the second element insulating layer of the second unit, the first insulation element and the third insulation element are placed to face each other in the thickness direction of the first element insulating layer, and the second insulation element and the fourth insulation element are placed to face each other in the thickness direction of the second element insulating layer.

2. The insulation chip according to claim 1, wherein at least one of the first unit, the second unit, or the third unit includes a positioning portion that positions the third unit relative to the first unit and the second unit.

3. The insulation chip according to claim 2, wherein the positioning portion includes one of a bump and a recess provided in at least one of the first unit or the second unit, and the other of the bump and the recess provided in the third unit.

4. The insulation chip according to claim 2, wherein the positioning portion includes a positioning mark formed on at least one of the first element surface of the first unit or the second element surface of the second unit.

5. The insulation chip according to claim 2, wherein
the first element insulating layer includes a first passivation film that forms the first element surface,
the second element insulating layer includes a second passivation film that forms the second element surface, and
the positioning portion is formed by cutting out both the first passivation film and the second passivation film in accordance with the third unit.

6. The insulation chip according to claim 1, wherein
the third unit includes a connection wiring line connecting the third insulation element and the fourth insulation element, and
the third insulation element, the fourth insulation element, and the connection wiring line are placed at a same position in the thickness direction of the third element insulating layer.

7. The insulation chip according to claim 6, wherein
the third insulation element includes a coil that has an open annular shape, the coil including a first coil end portion and a second coil end portion that are spaced apart from each other,
the fourth insulation element includes a coil that has an open annular shape, the coil including a third coil end portion and a fourth coil end portion that are spaced apart from each other, and
the connection wiring line includes:
a first connection wiring line connecting the first coil end portion and the third coil end portion; and
a second connection wiring line connecting the second coil end portion and the fourth coil end portion.

8. The insulation chip according to claim 6, wherein
the third insulation element includes multiple first concentric coils each having an open annular shape, the first concentric coils being in a concentric pattern,
the fourth insulation element includes multiple second concentric coils each having an open annular shape, the second concentric coils being in a concentric pattern,
each of the first concentric coils includes a first coil end portion and a second coil end portion spaced apart from each other,
each of the second concentric coils includes a third coil end portion and a fourth coil end portion spaced apart from each other, and
the connection wiring line includes:
a single first connection wiring line connecting the first coil end portions and the third coil end portions; and
a single second connection wiring line connecting the second coil end portions and the fourth coil end portions.

9. The insulation chip according to claim 6, wherein
the third insulation element includes multiple first concentric coils each having an open annular shape, the first concentric coils being in a concentric pattern,
the fourth insulation element includes multiple second concentric coils each having an open annular shape, the second concentric coils being in a concentric pattern,
each of the first concentric coils includes a first coil end portion and a second coil end portion spaced apart from each other,
each of the second concentric coils includes a third coil end portion and a fourth coil end portion spaced apart from each other, and
the connection wiring line includes:
multiple first connection wiring lines individually connecting the first coil end portions and the third coil end portions; and
multiple second connection wiring lines individually connecting the second coil end portions and the fourth coil end portions.

10. The insulation chip according to claim 1, wherein
the first unit includes a first pad electrically connected to the first insulation element, and
the first pad is located on an opposite side of the second unit with respect to the third unit in the first direction, and is exposed from the first element insulating layer in the thickness direction of the first element insulating layer.

11. The insulation chip according to claim 10, wherein a distance between the first pad and the third insulation element is greater than a distance between the first insulation element and the third insulation element, the distance between the first insulation element and the third insulation element being the distance in the thickness direction of the first element insulating layer.

12. The insulation chip according to claim 1, wherein
the second unit includes a second pad electrically connected to the second insulation element, and
the second pad is located on an opposite side of the first unit with respect to the third unit in the first direction, and is exposed from the second element insulating layer in the thickness direction of the second element insulating layer.

13. The insulation chip according to claim 12, wherein a distance between the second pad and the fourth insulation element is greater than a distance between the second insulation element and the fourth insulation element, the distance between the second insulation element and the fourth insulation element being the distance in the thickness direction of the second element insulating layer.

14. The insulation chip according to claim 1, wherein
the first unit includes a first circuit, and
the second unit includes a second circuit.

15. The insulation chip according to claim 14, wherein
the first circuit includes a transmitting circuit or a receiving circuit electrically connected to the first insulation element, and
the second circuit includes a transmitting circuit or a receiving circuit electrically connected to the second insulation element.

16. The insulation chip according to claim 15, wherein
the transmitting circuit or the receiving circuit of the first circuit is placed at a position overlapping the first insulation element as viewed from the thickness direction of the first element insulating layer, and
the transmitting circuit or the receiving circuit of the second circuit is placed at a position overlapping the second insulation element as viewed from the thickness direction of the second element insulating layer.

17. The insulation chip according to claim 1, wherein each of the first insulation element, the second insulation element, the third insulation element, and the fourth insulation element is a coil.

18. The insulation chip according to claim 1, wherein each of the first insulation element, the second insulation element, the third insulation element, and the fourth insulation element is an electrode plate.

19. A semiconductor device, comprising the insulation chip according to claim 1, the semiconductor device including:
a first die pad supporting the first unit;
a second die pad supporting the second unit and spaced apart from the first die pad in the first direction; and
sealing plastic that seals the first die pad, the second die pad, the first unit, the second unit, and the third unit.
